(19) United States
(12) Patent Application Publication
(10) Pub. No.: US 2025/0024710 A1
(43) Pub. Date: Jan. 16, 2025

(54) DISPLAY DEVICE AND METHOD OF MANUFACTURING THE SAME

(71) Applicant: Samsung Display Co., Ltd., Yongin-Si (KR)

(72) Inventors: Dong Han KANG, Yongin-si (KR); Shin Hyuk YANG, Yongin-si (KR); Woo Geun LEE, Yongin-si (KR); Jee Hoon KIM, Yongin-si (KR); Sung Gwon MOON, Yongin-si (KR)

(21) Appl. No.: 18/616,218

(22) Filed: Mar. 26, 2024

(30) Foreign Application Priority Data
Jul. 14, 2023 (KR) 10-2023-0091558

(51) Int. Cl. H10K 59/121; H10K 59/12; H10K 59/131; H10K 59/80; H10K 71/60

(52) U.S. Cl. CPC H10K 59/1216; H10K 59/1201; H10K 59/1213; H10K 59/131; H10K 59/80518; H10K 71/60

(57) ABSTRACT

A display device is disclosed that includes a substrate, a first metal layer disposed on the substrate, an active layer disposed on the first metal layer, a second metal layer disposed on the active layer, a third metal layer disposed on the second metal layer, a fourth metal layer disposed on the third metal layer, and a transistor and a capacitor disposed on the substrate. The transistor includes a gate electrode disposed in at least any one of the first metal layer and the second metal layer, and a drain electrode, a source electrode and an active region disposed in the active layer, The capacitor includes a first capacitor including a first electrode disposed in the first metal layer and a second electrode disposed in the second metal layer, a second capacitor including the second electrode and a third electrode disposed in the third metal layer, and a third capacitor including the third electrode and a fourth electrode disposed in the fourth metal layer.

This application claims the benefit of Korean Patent Application No. 10-2023-0091558,filed on Jul. 14, 2023, in the Korean Intellectual Property Office, the disclosure of which is incorporated herein in its entirety by reference.

### BACKGROUND

### 1. Field

The present disclosure relates to a display device and a method of manufacturing the same.

### 2. Description of the Related Art

Display devices are becoming increasingly important with the development of multimedia. Accordingly, various display devices such as liquid crystal display devices (LCDs) and organic light emitting diode display devices (OLEDs) are being developed.

Of the display devices, a self-light emitting display device includes a self-light emitting element such as an organic light emitting diode. The self-light emitting element may include two electrodes facing each other and a light emitting layer interposed between the two electrodes. When the self-light emitting element is an organic light emitting diode, electrons and holes provided from the two electrodes may be recombined in the light emitting layer to generate excitons. As the generated excitons change from an excited state to a ground state, light may be emitted.

Since self-light emitting display devices do not need a light source such as a backlight unit, they are low in power consumption, can be made lightweight and thin, and have a wide viewing angle, high luminance and contrast, and fast response speed. Due to these high-quality characteristics, the self-light emitting display devices are drawing attention as next-generation display devices.

As high-resolution display devices are gradually introduced, individual pixels are getting smaller. Accordingly, components constituting each pixel are also gradually getting smaller.

### SUMMARY

Aspects of the present disclosure may provide a display device and a method of manufacturing the same in which the area of each individual electrode of a capacitor is minimized, but the total capacitance of the capacitor is increased.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

An embodiment of a display device includes a substrate, a first metal layer disposed on the substrate, an active layer disposed on the first metal layer, a second metal layer disposed on the active layer, a third metal layer disposed on the second metal layer, a fourth metal layer disposed on the third metal layer, and a transistor and a capacitor disposed on the substrate, wherein the transistor includes a gate electrode disposed in at least any one of the first metal layer and the second metal layer, and a drain electrode, a source electrode and an active region disposed in the active layer, and wherein the capacitor includes a first capacitor including a first electrode disposed in the first metal layer and a second electrode disposed in the second metal layer, a second capacitor including the second electrode and a third electrode disposed in the third metal layer, and a third capacitor including the third electrode and a fourth electrode disposed in the fourth metal layer.

In an embodiment, the display device may further comprise, a first connection electrode disposed in the fourth metal layer and electrically connected to at least any one of the drain electrode and the source electrode, and a light emitting element disposed on the fourth metal layer and connected to the first connection electrode.

In an embodiment, the display device may comprise, a first overlap area in which the first electrode and the second electrode overlap, a second overlap area in which the second electrode and the third electrode overlap, and a third overlap area in which the third electrode and the fourth electrode overlap, wherein an area of the third overlap area is larger than an area of each of the first overlap area and an area of the second overlap area.

In an embodiment, the whole of the first overlap area and the whole of the second overlap area overlap the third overlap area.

In an embodiment, the light emitting element comprises a pixel electrode connected to the first connection electrode, and the pixel electrode comprises a different material from at least any one of the first through fourth electrodes.

In an embodiment, electrical conductivity of at least any one of the first through fourth electrodes is higher than electrical conductivity of the pixel electrode.

In an embodiment, the pixel electrode comprises at least any one of indium-tin-oxide (ITO), indium-zinc-oxide (IZO), zinc oxide (ZnO) and indium oxide (In2O3) and at least any one of silver (Ag), magnesium (Mg), aluminum (Al), platinum (Pt), lead (Pb), gold (Au), nickel (Ni), neodymium (Nd), iridium (Ir), chromium (Cr), lithium (Li) and calcium (Ca), and at least any one of the first through fourth electrodes comprises at least any one of molybdenum (Mo), aluminum (Al), chromium (Cr), gold (Au), titanium (Ti), nickel (Ni), neodymium (Nd) and copper (Cu).

In an embodiment, the display device may further comprise a first via layer disposed between the third metal layer and the fourth metal layer, wherein the first via layer comprises an opening or a groove overlapping the capacitor, and the fourth electrode is disposed in the opening or the groove.

In an embodiment, the fourth electrode is located at a lower level than the first connection electrode.

In an embodiment, the display device may further comprise a second connection electrode disposed in the third metal layer and connecting at least any one of the drain electrode and the source electrode to the first connection electrode, wherein a distance between the third electrode and the fourth electrode is smaller than a distance between the first connection electrode and the second connection electrode, in a thickness direction of the substrate.

In an embodiment, the display device may further comprise a first passivation layer disposed between the first via layer and the third metal layer, wherein the via layer includes the opening, the first passivation layer is exposed through the opening, and the fourth electrode is disposed on the first passivation layer exposed through the opening.

In an embodiment, the via layer comprises the groove, the first via layer comprises a valley which is a lowest surface disposed within the groove and a crest which is a highest surface disposed outside the groove, and the fourth electrode is disposed in the valley.

In an embodiment, the display device may further comprise a third connection electrode disposed in the third metal layer, wherein the third connection electrode is disposed between the fourth electrode and the second electrode.

In an embodiment, the third connection electrode electrically connects the fourth electrode and the second electrode to each other.

In an embodiment, the second electrode and the fourth electrode are electrically connected to each other, and the first electrode and the third electrode are electrically connected to each other.

In an embodiment, the gate electrode disposed in the first metal layer is a lower gate electrode, the gate electrode disposed in the second metal layer is an upper gate electrode, the first electrode and the third electrode have the same potential as at least any one of the source electrode and the lower gate electrode, and the second electrode and the fourth electrode have the same potential as the upper gate electrode.

In an embodiment, the second electrode is a part of the upper gate electrode.

In an embodiment, the first electrode is a part of the lower gate electrode.

An embodiment of a display device includes a substrate, a first metal layer disposed on the substrate, a second metal layer disposed on the first metal layer, a third metal layer disposed on the second metal layer, a first via layer disposed on the third metal layer and including a valley and a crest, a fourth metal layer disposed on the first via layer, and a capacitor disposed on the substrate, wherein the capacitor includes, a first electrode disposed in the first metal layer, a second electrode disposed in the second metal layer, a third electrode disposed in the third metal layer, and a fourth electrode disposed in the fourth metal layer, and wherein the fourth electrode is disposed in the valley of the first via layer.

In an embodiment, the second electrode and the fourth electrode are electrically connected to each other, and the first electrode and the third electrode are electrically connected to each other.

An embodiment of a method of manufacturing a display device, which includes a substrate, a first metal layer disposed on the substrate, a second metal layer disposed on the first metal layer, a third metal layer disposed on the second metal layer, a first via layer disposed on the third metal layer, and a capacitor disposed on the substrate, includes forming a groove in the first via layer using a halftone mask, and forming a fourth metal layer on the first via layer, wherein the capacitor includes, a first electrode disposed in the first metal layer, a second electrode disposed in the second metal layer, a third electrode disposed in the third metal layer, and a fourth electrode disposed in the fourth metal layer, and the fourth electrode is formed in the groove.

In an embodiment, the method may further comprise forming an opening by reducing a thickness of the first via layer after the forming of the groove, wherein the fourth electrode is formed in the opening in the forming of the fourth electrode.

In a display device and a method of manufacturing the same according to an embodiment of the present disclosure, the area of each individual electrode of a capacitor may be minimized, but the total capacitance of the capacitor may be increased.

However, the effects of the present disclosure are not restricted to the one set forth herein. The above and other effects of the present disclosure will become more apparent to one of daily skill in the art to which the present disclosure pertains by referencing the claims.

### BRIEF DESCRIPTION OF THE DRAWINGS

These and other aspects will become apparent and more readily appreciated from the following description of the embodiments, taken in conjunction with the accompanying drawings in which:

FIG. 1 is a schematic perspective view of a display device according to an embodiment;

FIG. 2 is a schematic cross-sectional view of the display device taken along line I-I′ of FIG. 1;

FIG. 3 is a schematic plan view of a display substrate and other components according to an embodiment;

FIG. 4 illustrates pixels and lines of the display device according to the embodiment;

FIG. 5 is a schematic plan view of a part of a display area of the display substrate according to the embodiment;

FIG. 6 is a cross-sectional view of the display device taken along line II-II′ of FIG. 5;

FIG. 7 is a circuit diagram of a pixel of the display device according to the embodiment;

FIG. 8 is a cross-sectional view of a first transistor and a capacitor of the display device according to the embodiment;

FIG. 9 is an enlarged view of area A of FIG. 8;

FIG. 10 is a schematic layout view of a part of the display device according to the embodiment;

FIGS. 11 through 13 are plan views of a first overlap area, a second overlap area, and a third overlap area according to an embodiment;

FIG. 14 is a cross-sectional view of a first transistor and a capacitor of a display device according to an embodiment;

FIG. 15 is an enlarged view of area B of FIG. 14;

FIG. 16 is a cross-sectional view of a first transistor and a capacitor of a display device according to an embodiment;

FIG. 17 is a cross-sectional view of a first transistor and a capacitor of a display device according to an embodiment;

FIG. 18 is a flowchart illustrating a method of manufacturing the display device according to the embodiment of FIG. 14;

FIGS. 19 and 20 are cross-sectional views illustrating operation S100 of FIG. 18;

FIG. 21 is a cross-sectional view illustrating operation S200 of FIG. 18;

FIG. 22 is a cross-sectional view illustrating operation S300 of FIG. 18;

FIG. 23 is a cross-sectional view illustrating operation S400 of FIG. 18;

FIGS. 24 and 25 are cross-sectional views illustrating operation S500 of FIG. 18;

FIG. 26 is a cross-sectional view illustrating operation S600 of FIG. 18; and

FIG. 27 is a cross-sectional view illustrating operation S700 of FIG. 18.

### DETAILED DESCRIPTION

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

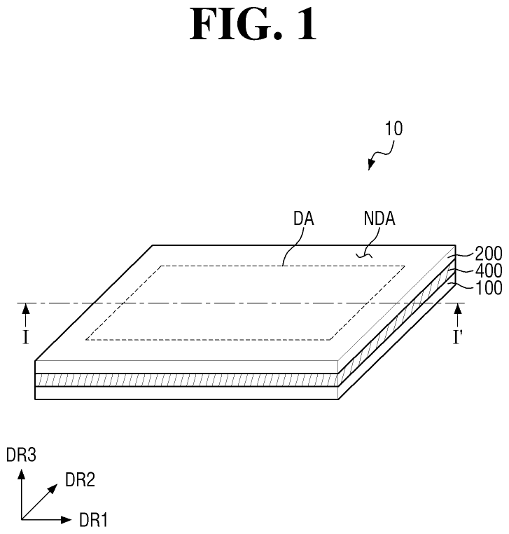

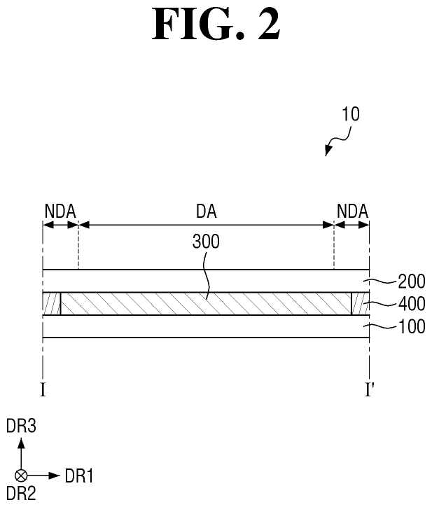

FIG. 1 is a schematic perspective view of a display device 10 according to an embodiment. FIG. 2 is a schematic cross-sectional view of the display device 10 taken along line I-I′ of FIG. 1.

Referring to FIGS. 1 and 2, the display device 10 may be applied to various electronic devices including small and medium-sized electronic equipment such as tablet personal computers (PCs), smartphones, car navigation units, cameras, center information displays (CIDs) provided in vehicles, wristwatch type electronic devices, personal digital assistants (PDAs), portable multimedia players (PMPs) and game consoles and medium and large-sized electronic equipment such as televisions, outdoor billboards, monitors, PCs and notebook computers. These are merely presented as examples, and the display device 10 may also be employed in other electronic devices as long as not departing from the spirit of the present disclosure.

In an embodiment, the display device 10 may be rectangular in plan view. The display device 10 may include two long sides extending in a first direction DR1 and two short sides extending in a second direction DR2 crossing the first direction DR1. Each corner where a long side of the display device 10 meets a short side may be right-angled. However, the present disclosure is not limited thereto, and each corner may also form a curved surface. In an embodiment, the long sides may extend in the second direction DR2, and the short sides may extend in the first direction DR1. The planar shape of the display device 10 is not limited to the above example but may also be a circular shape or other shapes.

In the drawings, the first direction DR1 and the second direction DR2 are horizontal directions crossing each other. For example, the first direction DR1 and the second direction DR2 may be orthogonal to each other. In addition, a third direction DR3 may cross the first direction DR1 and the second direction DR2, for example, may be a vertical direction orthogonal to the first direction DR1 and the second direction DR2. Unless otherwise defined, in the present specification, a direction indicated by an arrow of each of the first through third directions DR1 through DR3 may be referred to as one side, and the opposite direction may be referred to as the other side. In addition, in the present specification, “on”, “upper side”, “above”, “top”, and “upper surface” refer to a direction in which the arrow of the third direction DR3 points in the drawings, and “under”, “lower side”, “below”, “bottom”, and “lower surface” refer to a direction opposite to the direction in which the arrow of the third direction DR3 points in the drawings.

The display device 10 may include a display area DA displaying an image and a non-display area NDA not displaying an image. In an embodiment, the non-display area NDA may be located around the display area DA and may surround the display area DA.

As for the schematic stacked structure of the display device 10, in an embodiment, the display device 10 may include a display substrate 100 and a color conversion substrate 200 facing the display substrate 100 and may further include a sealing part 400 bonding the display substrate 100 and the color conversion substrate 200 together and a filler 300 filling a space between the display substrate 100 and the color conversion substrate 200.

The display substrate 100 may include elements and circuits for displaying an image, for example, a pixel circuit such as a switching element, a pixel defining layer defining an emission area and a non-emission area, which will be described later, in the display area DA, and a self-light emitting element. In an embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For ease of description, a case where the self-light emitting clement is an organic light emitting diode will be described below as an example.

The color conversion substrate 200 may be located on the display substrate 100 and may face the display substrate 100. In an embodiment, the color conversion substrate 200 may include a color conversion pattern that converts the color of incident light. In an embodiment, the color conversion pattern may include at least any one of a color filter and a wavelength conversion pattern.

The sealing part 400 may be located between the display substrate 100 and the color conversion substrate 200 in the non-display area NDA. The sealing part 400 may be disposed along edges of the display substrate 100 and the color conversion substrate 200 in the non-display area NDA to surround the display area DA in plan view. The display substrate 100 and the color conversion substrate 200 may be bonded to each other by the sealing part 400.

In an embodiment, the sealing part 400 may be made of an organic material. For example, the sealing part 400 may be made of, but not limited to, epoxy-based resin.

The filler 300 may be located in the space formed between the display substrate 100 and the color conversion substrate 200 and surrounded by the sealing part 400. The filler 300 may fill the space between the display substrate 100 and the color conversion substrate 200.

In an embodiment, the filler 300 may be made of a material that can transmit light. In an embodiment, the filler 300 may be made of an organic material. For example, the filler 300 may be made of, but not limited to, a silicon-based organic material or an epoxy-based organic material. In an embodiment, the filler 300 may also be omitted.

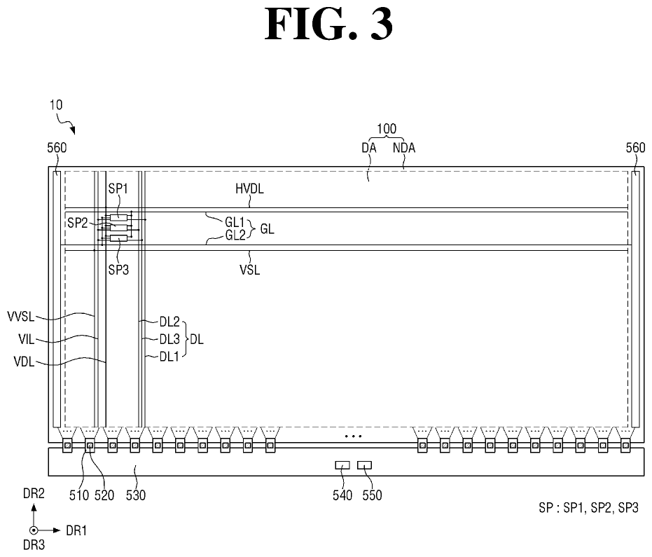

FIG. 3 is a schematic plan view of a display substrate 100 and other components according to an embodiment.

Referring to FIG. 3, the display device 10 may include the display substrate 100, flexible films 510, display drivers 520, a circuit board 530, a timing controller 540, a power supply 550, and gate drivers 560.

The display substrate 100 may be rectangular in plan view. For example, the display substrate 100 may be shaped like a rectangular plane having long sides in the first direction DR1 and short sides in the second direction DR2. Each corner where a long side extending in the first direction DR1 meets a short side extending in the second direction DR2 may be right-angled or may be rounded with a predetermined curvature. The planar shape of the display substrate 100 is not limited to a rectangular shape and may also be another polygonal shape, a circular shape, or an oval shape. For example, the display substrate 100 may be formed flat, but the present disclosure is not limited thereto. For another example, the display substrate 100 may be formed to be bent with a predetermined curvature.

The display substrate 100 may include a display area DA and a non-display area NDA.

The display area DA may be an area for displaying an image and may be defined as a central area of the display substrate 100. The display area DA may include pixels SP, gate lines GL, data lines DL, initialization voltage lines VIL, first voltage lines VDL, horizontal voltage lines HVDL, vertical voltage lines VVSL, and second voltage lines VSL. The pixels SP may be respectively formed in pixel areas intersected by the data lines DL and the gate lines GL. The pixels SP may include first through third pixels SP1 through SP3. Each of the first through third pixels SP1 through SP3 may be connected to a gate line GL and a data line DL. Each of the first through third pixels SP1 through SP3 may be defined as a minimum unit area that outputs light.

Each of the first through third pixels SP1 through SP3 may include an organic light emitting diode including an organic light emitting layer, a quantum dot light emitting diode including a quantum dot light emitting layer, a micro light emitting diode, or an inorganic light emitting diode including an inorganic semiconductor.

The first pixels SP1 may emit light of a first color or red light, the second pixels SP2 may emit light of a second color or green light, and the third pixels SP3 may emit light of a third color or blue light. Pixel circuits of the first pixels SP1, pixel circuits of the second pixels SP2, and pixel circuits of the third pixels SP3 may be arranged in a direction opposite to the second direction DR2, but the order of the pixel circuits is not limited thereto.

The gate lines GL may include first gate lines GL1 and second gate lines GL2. The first gate lines GL1 may extend in the first direction DR1 and may be spaced apart from each other in the second direction DR2. The first gate lines GL1 may receive a first gate signal from the gate drivers 560 and supply the first gate signal to the first through third pixels SP1 through SP3.

The second gate lines GL2 may extend in the first direction DR1 and may be spaced apart from each other in the second direction DR2. The second gate lines GL2 may receive a second gate signal from the gate drivers 560 and supply the second gate signal to the first through third pixels SP1 through SP3.

The data lines DL may extend in the second direction DR2 and may be spaced apart from each other in the first direction DR1. The data lines DL may include first through third data lines DL1 through DL3. The first through third data lines DL1 through DL3 may supply data voltages to the first through third pixels SP1 through SP3, respectively.

The initialization voltage lines VIL may extend in the second direction DR2 and may be spaced apart from each other in the first direction DR1. The initialization voltage lines VIL may supply initialization voltages received from the display drivers 520 to the pixel circuits of the first through third pixels SP1 through SP3. The initialization voltage lines VIL may receive sensing signals from the pixel circuits of the first through third pixels SP1 through SP3 and supply the sensing signals to the display drivers 520.

The first voltage lines VDL may extend in the second direction DR2 and may be spaced apart from each other in the first direction DR1. The first voltage lines VDL may supply a driving voltage or a high potential voltage received from the power supply 550 to the first through third pixels SP1 through SP3.

The horizontal voltage lines HVDL may extend in the first direction DR1 and may be spaced apart from each other in the second direction DR2. The horizontal voltage lines HVDL may be connected to the first voltage lines VDL. The horizontal voltage lines HVDL may receive a driving voltage or a high potential voltage from the first voltage lines VDL.

The vertical voltage lines VVSL may extend in the second direction DR2 and may be spaced apart from each other in the first direction DR1. The vertical voltage lines VVSL may be connected to the second voltage lines VSL. The vertical voltage lines VVSL may supply a low potential voltage received from the power supply 550 to the second voltage lines VSL.

The second voltage lines VSL may extend in the first direction DR1 and may be spaced apart from each other in the second direction DR2. The second voltage lines VSL may supply a low potential voltage to the first through third pixels SP1 through SP3.

The connection relationship between the pixels SP, the gate lines GL, the data lines DL, the initialization voltage lines VIL, the first voltage lines VDL, the horizontal voltage lines HVDL, the vertical voltage lines VVSL, and the second voltage lines VSL may be designed and changed according to the number and arrangement of the pixels SP.

The non-display area NDA may be defined as an area other than the display area DA in the display substrate 100. For example, the non-display area NDA may include fan-out lines connecting the data lines DL, the initialization voltage lines VIL, the first voltage lines VDL and the vertical voltage lines VVSL to the display drivers 520 and may include the gate drivers 560 and pad units (not illustrated) connected to the flexible films 510.

The flexible films 510 may be connected to the pad units disposed on a lower side of the non-display area NDA. Input terminals disposed on one side of the flexible films 510 may be attached to the circuit board 530 by a film attaching process, and output terminals disposed on the other side of the flexible films 510 may be attached to the pad units by a film attaching process. For example, each of the flexible films 510 may be bent like a tape carrier package or a chip on film. The flexible films 510 may be bent toward the bottom of the display substrate 100 to reduce a bezel area of the display device 10.

The display drivers 520 may be mounted on the flexible films 510. For example, the display drivers 520 may be implemented as integrated circuits (ICs). The display drivers 520 may receive digital video data and a data control signal from the timing controller 540, convert the digital video data into analog data voltages according to the data control signal, and supply the analog data voltages to the data lines DL through the fan out lines.

The circuit board 530 may support the timing controller 540 and the power supply 550 and may supply signals and power to the display drivers 520. For example, the circuit board 530 may supply a signal supplied from the timing controller 540 and a power supply voltage supplied from the power supply 550 to the flexible films 510 and the display drivers 520 in order to display an image in each pixel. To this end, signal lines and power lines may be provided on the circuit board 530.

The timing controller 540 may be mounted on the circuit board 530 and may receive image data and a timing synchronization signal from a display driving system or a graphics device through a user connector provided on the circuit board 530. The timing controller 540 may generate digital video data by arranging the image data according to the pixel arrangement structure based on the timing synchronization signal and supply the generated digital video data to the display drivers 520. The timing controller 540 may generate a data control signal and a gate control signal based on the timing synchronization signal. The timing controller 540 may control the data voltage supply timing of the display drivers 520 based on the data control signal and may control the gate signal supply timing of the gate drivers 560 based on the gate control signal.

The power supply 550 may be disposed on the circuit board 530 to supply a power supply voltage to the flexible films 510 and the display drivers 520. For example, the power supply 550 may generate a driving voltage or a high potential voltage and supply the driving voltage or the high potential voltage to the first voltage lines VDL, may generate a low potential voltage and supply the low potential voltage to the vertical voltage lines VVSL, and may generate an initialization voltage and supply the initialization voltage to the initialization voltage lines VIL.

The gate drivers 560 may be disposed on left and right sides of the non-display area NDA. The gate drivers 560 may generate gate signals based on a gate control signal supplied from the timing controller 540. The gate control signal may include, but is not limited to, a start signal, a clock signal, and a power supply voltage. The gate drivers 560 may supply the gate signals to the gate lines GL according to a set order.

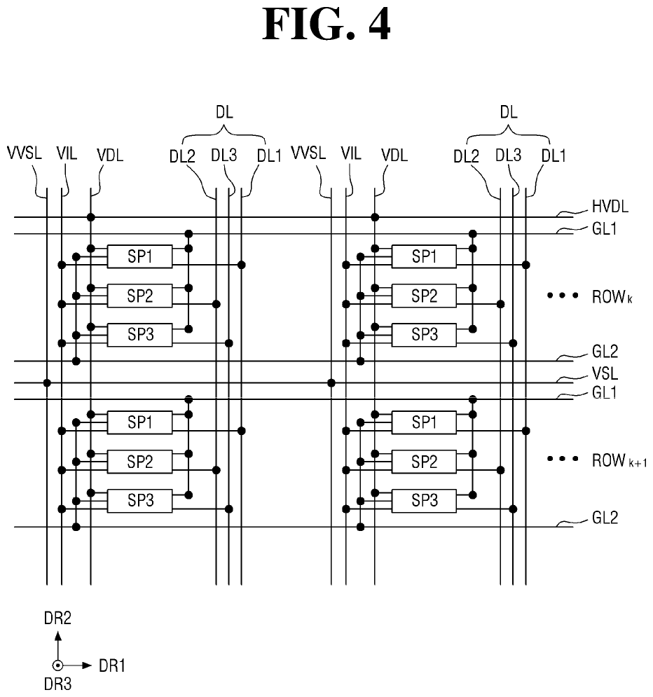

FIG. 4 illustrates pixels and lines of the display device 10 according to the embodiment.

Referring to FIG. 4 in addition to FIG. 3, the pixels SP may include the first through third pixels SP1 through SP3. The pixel circuits of the first pixels SP1, the pixel circuits of the second pixels SP2, and the pixel circuits of the third pixels SP3 may be arranged in the direction opposite to the second direction DR2, but the order of the pixel circuits is not limited thereto.

Each of the first through third pixels SP1 through SP3 may be connected to a first voltage line VDL, an initialization voltage line VIL, a gate line GL, and a data line DL.

The first voltage lines VDL may extend in the second direction DR2. The first voltage lines VDL may be disposed on left sides of the pixel circuits of the first through third pixels SP1 through SP3. The first voltage lines VDL may supply a driving voltage or a high potential voltage to transistors of the first through third pixels SP1 through SP3.

A horizontal voltage line HVDL may extend in the first direction DR1. The horizontal voltage line HVDL may be disposed above a first gate line GL1 disposed in a k^{th} row ROWₖ (where k is a positive integer). The horizontal voltage line HVDL may be connected to the first voltage lines VDL. The horizontal voltage line HVDL may receive driving voltages or high potential voltages from the first voltage lines VDL.

The initialization voltage lines VIL may extend in the second direction DR2. The initialization voltage lines VIL may be disposed on left sides of auxiliary lines branching from each second gate line GL2 in the second direction DR2. The initialization voltage lines VIL may be disposed between the auxiliary lines, which branch from each second gate line GL2 in the second direction DR2, and the vertical voltage lines VVSL. The initialization voltage lines VIL may supply an initialization voltage to the pixel circuits of the first through third pixels SP1 through SP3. The initialization voltage lines VIL may receive sensing signals from the pixel circuits of the first through third pixels SP1 through SP3 and supply the sensing signals to the display drivers 520.

The vertical voltage lines VVSL may extend in the second direction DR2. The vertical voltage lines VVSL may be disposed on left sides of the initialization voltage lines VIL. The vertical voltage lines VVSL may be connected between the power supply 550 and a second voltage line VSL. The vertical voltage lines VVSL may supply a low potential voltage received from the power supply 550 to the second voltage line VSL.

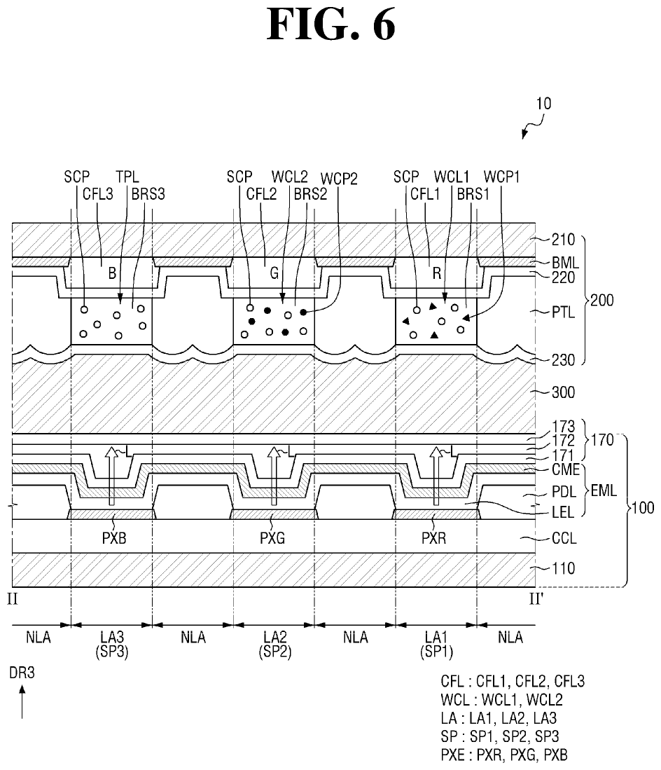

The second voltage line VSL may extend in the first direction DR1. The second voltage line VSL may be disposed above a first gate line GL1 disposed in a (k+1)^{th} row ROWₖ₊₁. The second voltage line VSL may supply a low potential voltage received from the vertical voltage lines VVSL to a light emitting element layer EML (see FIG. 6) of the first through third pixels SP1 through SP3.

The first gate lines GL1 may extend in the first direction DR1. The first gate lines GL1 may be disposed above the pixel circuits of the first pixels SP1. At least a portion of each first gate line GL1 may extend in the direction opposite to the second direction DR2. For example, each of the first gate lines GL1 may include auxiliary lines branching to right sides of the first through third pixels SP1 through SP3 and extending in the direction opposite to the second direction DR2. The auxiliary lines of each of the first gate lines GL1 may be disposed on the right sides of the pixel circuits of the first through third pixels SP1 through SP3. Each of the first gate lines GL1 may supply a first gate signal received from the gate drivers 560 to the pixel circuits of the first through third pixels SP1 through SP3 through the auxiliary lines extending in the direction opposite to the second direction DR2.

The second gate lines GL2 may extend in the first direction DR1. The second gate lines GL2 may be disposed below the pixel circuits of the third pixels SP3. At least a portion of each second gate line GL2 may extend in the second direction DR2. For example, each of the second gate lines GL2 may include auxiliary lines branching to left sides of the first voltage lines VDL and extending in the second direction DR2. The auxiliary lines of each of the second gate lines GL2 may be disposed on the left sides of the first voltage lines VDL. Each of the second gate lines GL2 may supply a second gate signal received from the gate drivers 560 to the pixel circuits of the first through third pixels SP1 through SP3 through the auxiliary lines extending in the second direction DR2.

The data lines DL may extend in the second direction DR2. The data lines DL may supply data voltages to the pixels SP. The data lines DL may include the first through third data lines DL1 through DL3.

The second data lines DL2 may extend in the second direction DR2. The second data lines DL2 may be disposed on right sides of the auxiliary lines of each first gate line GL1. The second data lines DL2 may supply data voltages received from the display drivers 520 to the pixel circuits of the second pixels SP2.

The third data lines DL3 may extend in the second direction DR2. The third data lines DL3 may be disposed on right sides of the second data lines DL2. The third data lines DL3 may supply data voltages received from the display drivers 520 to the pixel circuits of the third pixels SP3.

The first data lines DL1 may extend in the second direction DR2. The first data lines DL1 may be disposed on right sides of the third data lines DL3. The first data lines DL1 may supply data voltages received from the display drivers 520 to the pixel circuits of the first pixels SP1.

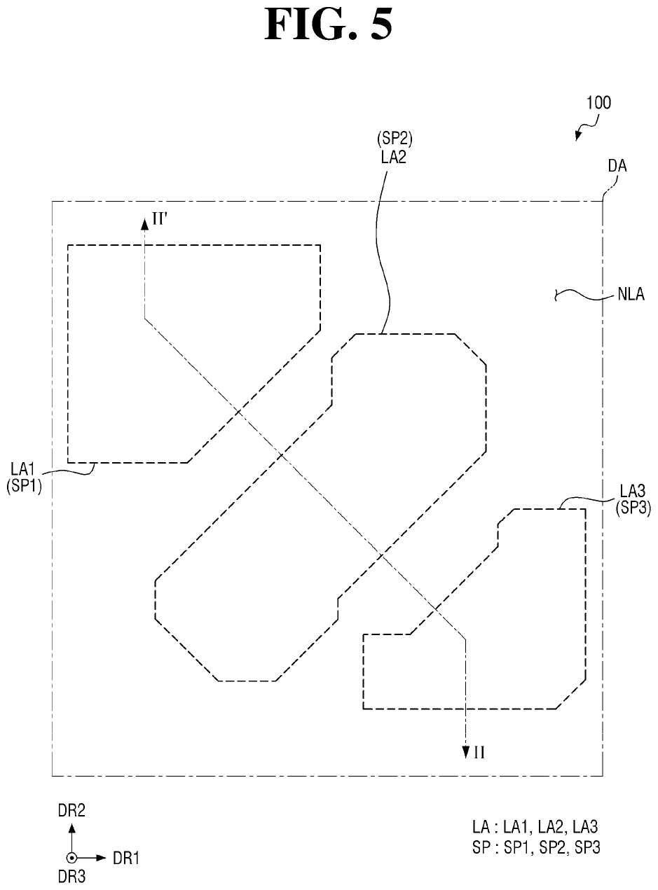

FIG. 5 is a schematic plan view of a part of the display area DA of the display substrate 100 according to the embodiment.

Referring to FIG. 5 in addition to FIGS. 1 and 2, a plurality of emission areas LA and a non-emission area NLA may be defined in the display area DA of the display substrate 100. The emission areas LA may be areas where light generated by light emitting elements of the display substrate 100 is emitted to the outside of the display substrate 100, and the non-emission area NLA may be an area where the light is not emitted to the outside.

The emission areas LA may include a first emission area LA1, a second emission area LA2, and a third emission area LA3.

Light emitted from the display substrate 100 to the color conversion substrate 200 in the emission areas LA may be light of the third color. In an embodiment, the light of the third color may be blue light and may have a peak wavelength in the range of about 440 to about 480 nm. The peak wavelength may refer to a wavelength having maximum intensity in a wavelength region. However, the present disclosure is not limited thereto, and the light emitted from the display substrate 100 to the color conversion substrate 200 in the emission areas LA may also be light in an ultraviolet region.

The first emission area LA1, the second emission area LA2, and the third emission area LA3 may constitute a first pixel SP1, a second pixel SP2, and a third pixel SP3, respectively. The first emission area LA1, the second emission area LA2, and the third emission area LA3 may be repeatedly disposed over the entire display area DA along the first direction DR1 and the second direction DR2. The first emission area LA1, the second emission area LA2, and the third emission area LA3 may constitute one unit color pixel.

The first through third emission areas LAI through LA3 may be disposed in a diagonal direction defined by the directions opposite to the first direction DR1 and the second direction DR2. For example, in one unit color pixel, the first emission area LA1 may be generally disposed at an upper left corner in plan view, the second emission area LA2 may be generally disposed at a center in plan view, and the third emission area LA3 may be generally disposed at a lower right corner in plan view.

However, the arrangement order of the first through third emission areas LA1 through LA3 is not limited thereto. In addition, in an embodiment, the first through third emission areas LA1 through LA3 may be arranged in a diagonal direction defined by the first direction DR1 and the second direction DR2.

In an embodiment, the first emission area LA1 may be a polygon having certain widths in the first direction DR1 and the second direction DR2. In the drawing, a pentagon is illustrated as an example of the first emission area LA1. The second emission area LA2 may be a polygon having a certain width and extending in the diagonal direction defined by the first direction DR1 and the second direction DR2. In the drawing, a polygon having steps at both ends is illustrated as an example of the second emission area LA2. The third emission area LA3 may be a polygon having certain widths in the first direction DR1 and the second direction DR2. In the drawing, a polygon including portions protruding in the direction opposite to the first direction DR1 and in the second direction DR2 is illustrated as an example of the third emission area LA3.

As illustrated in the drawing, the widths and shapes of the first through third emission areas LA1 through LA3 may be different from each other. For example, the first emission area LA1 may have similar widths in the first direction DR1 and the second direction DR2. The second emission area LA2 may have a wide width in the diagonal direction defined by the first direction DR1 and the second direction DR2 and may have a narrow width in the diagonal direction defined by the directions opposite to the first direction DR1 and the second direction DR2. Therefore, the second emission area LA2 may be shaped like a polygon generally extending in the diagonal direction defined by the first direction DR1 and the second direction DR2. The third emission area LA3 may have similar widths in the first direction DR1 and the second direction DR2. However, the present disclosure is not limited thereto. In some embodiments, the first through third emission areas LA1 through LA3 may all have the same shape.

In the display device 10 according to the current embodiment, since the first through third emission areas LA1 through LA3 are disposed in a diagonal direction, a difference in the distribution of the emission areas LA between upper, lower, left and right parts of one unit color pixel can be reduced. Accordingly, a color cast phenomenon in which a color other than white or black is displayed at a boundary between white and black can be minimized in the upper, lower, left and right parts of the pixel.

In addition, since the second emission area LA2 extends long in the diagonal direction defined by the first direction DR1 and the second direction DR2, the difference in the distribution of the emission areas LA between the upper, lower, left and right parts of one unit color pixel can be further reduced, which, in turn, minimizes the color cast phenomenon in the upper, lower, left and right parts.

The non-emission area NLA may be located around the emission areas LA of the display substrate 100 in the display area DA. The non-emission area NLA may be located not only around the emission areas LA, but also between the first emission area LA1 and the second emission area LA2, between the second emission area LA2 and the third emission area LA3, and between the third emission area LA3 and the first emission area LA1.

In some embodiments, boundaries between the emission areas LA and the non-emission area NLA may be defined by openings of a pixel defining layer PDL (see FIG. 6) to be described later and outer walls surrounding the openings.

Light emitted from the emission areas LA of the display substrate 100 may pass through light transmitting areas of the color conversion substrate 200 and then may be provided to the outside of the display device 10.

FIG. 6 is a cross-sectional view of the display device 10 taken along line II-II′ of FIG. 5.

Referring to FIG. 6 in addition to FIG. 5, the display device 10 may include the display substrate 100, the color conversion substrate 200 facing the display substrate 100, and the filler 300 bonding the display substrate 100 and the color conversion substrate 200 together.

The display substrate 100 may include a first substrate 110, a circuit layer CCL, a light emitting element layer EML, and an encapsulation structure 170.

The first substrate 110 may include a transparent material. For example, the first substrate 110 may include a transparent insulating material such as glass or quartz. The first substrate 110 may be a rigid substrate. However, the first substrate 110 is not limited thereto. The first substrate 110 may also include plastic such as polyimide and may have flexible properties so that it can be curved, bent, folded, or rolled.

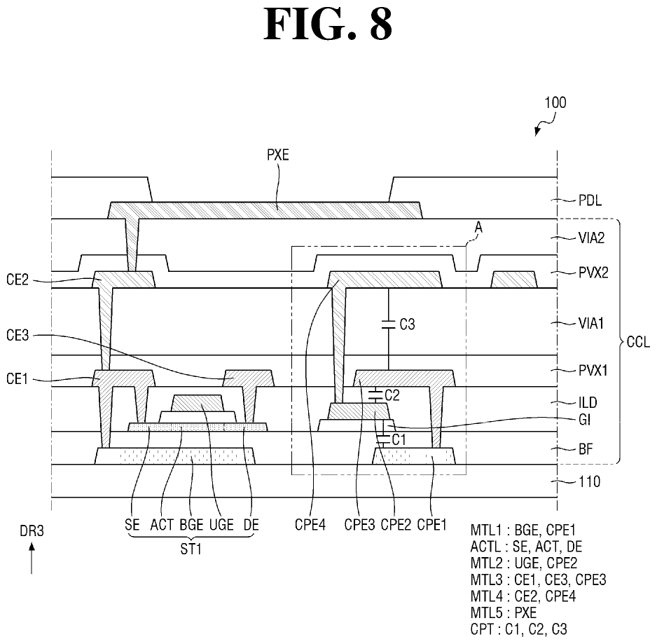

The circuit layer CCL (e.g., thin-film transistor layer) may be disposed on the first substrate 110. The circuit layer CCL will be described in detail later with reference to FIG. 8, etc.

The light emitting element layer EML may be disposed on the circuit layer CCL. The light emitting element layer EML may include pixel electrodes PXE, a pixel defining layer PDL, a light emitting layer LEL, and a common electrode CME.

The pixel electrodes PXE may be first electrodes, e.g., anodes of light emitting diodes. The pixel electrodes PXE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is located close to the light emitting layer LEL. The pixel electrodes PXE may have, but are not limited to, a multilayer structure of ITO/Mg, ITO/MgF, ITO/Ag, or ITO/Ag/ITO.

The pixel electrodes PXE may include a first pixel electrode PXR, a second pixel electrode PXG, and a third pixel electrode PXB. The first pixel electrode PXR may overlap the first emission area LA1. The second pixel electrode PXG may overlap the second emission area LA2. The third pixel electrode PXB may overlap the third emission area LA3.

The pixel defining layer PDL may be disposed on a surface of the first substrate 110 along the boundaries of the pixels SP. The pixel defining layer PDL may be disposed on the pixel electrodes PXE and may include openings exposing the pixel electrodes PXE. The emission areas LA and the non-emission area NLA may be defined by the pixel defining layer PDL and its openings.

The pixel defining layer PDL may include an organic insulating material such as polyacrylates resin. epoxy resin. phenolic resin, polyamides resin, polyimides resin, unsaturated polyesters resin, polyphenylenethers resin, polyphenylenesulfides resin, or benzocyclobutene (BCB). The pixel defining layer PDL may also include an inorganic material.

The light emitting layer LEL may be disposed on the pixel electrodes PXE exposed by the pixel defining layer PDL. The light emitting layer LEL may contact not only the pixel electrodes PXE, but also side and upper surfaces of the pixel defining layer PDL. The light emitting layer LEL may be connected without distinguishing between the emission areas LA and between the pixels SP. The light emitting layer LEL may be disposed over the entire surface without distinguishing between the emission areas LA and between the pixels SP. Accordingly, the light emitting layer LEL of the emission areas LA1 through LA3 may emit light having the same wavelength. For example, the light emitting layer LEL of the emission areas LA1 through LA3 may emit blue light or ultraviolet light, and a wavelength conversion layer WCL included in the color conversion substrate 200 to be described later may enable each pixel SP to display a corresponding color.

In an embodiment, light emitting layers LEL may be respectively disposed in the emission areas LA1 through LA3 separated by the pixel defining layer PDL. In this case, the light emitting layers LEL of the emission areas LA1 through LA3 may emit light having the same wavelength.

In an embodiment in which the display device 10 is an organic light emitting display device, the light emitting layer LEL may include an organic layer including an organic material. The organic layer may include an organic light emitting layer. In some cases, the organic layer may further include at least one of a hole injection layer, a hole transport layer, an electron transport layer, and an electron injection layer as an auxiliary layer for assisting light emission. In an embodiment, when the display device 10 is a micro-LED display device or a nano-LED display device, the light emitting layer LEL may include an inorganic material such as an inorganic semiconductor.

In some embodiments, the light emitting layer LEL may have a tandem structure including a plurality of organic light emitting layers overlapping each other in a thickness direction and a charge generation layer disposed between them. The organic light emitting layers overlapping each other may emit light of the same wavelength or may emit light of different wavelengths. At least some layers of the light emitting layer LEL of each pixel SP may be separated from or connected to those of the light emitting layer LEL of a neighboring pixel SP by the pixel defining layer PDL.

The common electrode CME may be disposed on the light emitting layer LEL. The common electrode CME may be connected without distinguishing between the emission areas LA and the pixels SP. The common electrode CME may be a whole-surface electrode disposed over the entire surface without distinguishing between the emission areas LA and between the pixels SP. The common electrode CME may be second electrodes, e.g., cathodes of the light emitting diodes. The common electrode CME may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The common electrode CME may further include a transparent metal oxide layer disposed on the material layer having a small work function.

The pixel electrodes PXE, the light emitting layer LEL, and the common electrode CME may constitute light emitting elements (e.g., organic light emitting diodes). Light emitted from the light emitting layer LEL may be output upward through the common electrode CME.

The encapsulation structure 170 may be disposed on the common electrode CME. The encapsulation structure 170 may include at least one thin-film encapsulation layer. For example, the encapsulation structure 170 may include a first encapsulation inorganic layer 171, an encapsulation organic layer 172, and a second encapsulation inorganic layer 173.

The first encapsulation inorganic layer 171 may be disposed on the light emitting element layer EML. The first encapsulation inorganic layer 171 may include silicon nitride (SiNₓ), silicon oxide (SiOₓ), or silicon oxynitride (SiOₓN_{y}).

The encapsulation organic layer 172 may be disposed on the first encapsulation inorganic layer 171. The encapsulation organic layer 172 may include an organic insulating material such as polyacrylates resin, epoxy resin, phenolic resin, polyamides resin, polyimides resin, unsaturated polyesters resin, polyphenylenethers resin. polyphenylenesulfides resin, or benzocyclobutene (BCB).

The second encapsulation inorganic layer 173 may be disposed on the encapsulation organic layer 172. The second encapsulation inorganic layer 173 may include the same material as the first encapsulation inorganic layer 171 described above. For example, the second encapsulation inorganic layer 173 may include silicon nitride (SiNₓ), silicon oxide (SiOₓ), or silicon oxynitride (SiOₓN_{y}).

In some embodiments, some layers of the encapsulation structure 170 or the entire encapsulation structure 170 may be omitted. When the encapsulation structure 170 is omitted, the filler 300, the sealing part 400 and the color conversion substrate 200 may be directly disposed on the light emitting element layer EML and may directly perform an encapsulation function.

The color conversion substrate 200 may be disposed on the encapsulation structure 170 to face the display substrate 100. The color conversion substrate 200 may include a second substrate 210, a light blocking member BML, color filter layers CFL, a first capping layer 220, a partition wall PTL, a wavelength conversion layer WCL, a light transmitting layer TPL, and a second capping layer 230.

The second substrate 210 may include a transparent material. The second substrate 210 may include a transparent insulating material such as glass or quartz. The second substrate 210 may be a rigid substrate. However, the second substrate 210 is not limited thereto. The second substrate 210 may also include plastic such as polyimide or may have flexible properties so that it can be curved, bent, folded, or rolled.

The second substrate 210 may be the same substrate as the first substrate 110, but may have a different material, thickness, and transmittance from the first substrate 110. For example, the second substrate 210 may have higher transmittance than the first substrate 110. The second substrate 210 may be thicker or thinner than the first substrate 110.

The light blocking member BML may be disposed on a surface of the second substrate 210, which faces the first substrate 110, along the boundaries of the pixels SP. The light blocking member BML may overlap the pixel defining layer PDL of the display substrate 100 and may be located in the non-emission area NLA. The light blocking member BML may include openings exposing the surface of the second substrate 210 which overlaps the emission areas LA. The light blocking member BML may be formed in a lattice shape in plan view.

The light blocking member BML may include an organic material. The light blocking member BML may reduce color distortion due to reflection of external light by absorbing the external light. In addition, the light blocking member BML may prevent light emitted from the light emitting layer LEL from intruding into adjacent pixels SP.

In an embodiment, the light blocking member BML may absorb all visible light wavelengths. The light blocking member BML may include a light absorbing material. For example, the light blocking member BML may be made of a material used as a black matrix of the display device 10.

In an embodiment, the light blocking member BML may absorb light of a specific wavelength among the visible light wavelengths and transmit light of another specific wavelength. For example, the light blocking member BML may include the same material as a color filter layer CFL. Specifically, the light blocking member BML may be made of the same material as a blue color filter layer. In some embodiments, the light blocking member BML may be integrally formed with the blue color filter layer. The light blocking member BML may also be omitted.

The color filter layers CFL may be disposed on the surface of the second substrate 210 on which the light blocking member BML is disposed. The color filter layers CFL may be disposed on the surface of the second substrate 210 exposed through the openings of the light blocking member BML. Further, each of the color filter layers CFL may be disposed on a portion of the adjacent light blocking member BML.

The color filter layers CFL may include a first color filter layer CFL1 disposed in the first pixel SP1, a second color filter layer CFL2 disposed in the second pixel SP2, and a third color filter layer CFL3 disposed in the third pixel SP3. Each color filter layer CFL may include a colorant such as a dye or pigment that absorbs wavelengths other than a corresponding color wavelength. The first color filter layer CFL1 may be a red color filter layer, the second color filter layer CFL2 may be a green color filter layer, and the third color filter layer CFL3 may be a blue color filter layer. Although neighboring color filter layers CFL are spaced apart from each other on the light blocking member BML in the drawing, they may also at least partially overlap each other on the light blocking member BML.

The first capping layer 220 may be disposed on the color filter layers CFL. The first capping layer 220 may prevent damage to or contamination of the color filter layers CFL by preventing penetration of impurities such as moisture or air from the outside into the color filter layers CFL.

The first capping layer 220 may directly contact surfaces (lower surfaces in FIG. 6) of the color filter layers CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, or silicon oxynitride.

The partition wall PTL may be disposed on the first capping layer 220. The partition wall PTL may be located in the non-emission area NLA. The partition wall PTL may overlap the light blocking member BML. The partition wall PTL may include openings exposing the color filter layers CFL. The partition wall PTL may include a photosensitive organic material, but the present disclosure is not limited thereto. The partition wall PTL may further include a light blocking material.

The wavelength conversion layer WCL or the light transmitting layer TPL or both may be disposed in spaces exposed by the openings of the partition wall PTL. The wavelength conversion layer WCL and the light transmitting layer TPL may be formed by an inkjet process using the partition wall PTL as a bank, but the present disclosure is not limited thereto.

In an embodiment in which the light emitting layer LEL of each pixel SP emits light of the third color, the wavelength conversion layer WCL may include a first wavelength conversion pattern WCL1 disposed in the first pixel SP1 and a second wavelength conversion pattern WCL2 disposed in the second pixel SP2. The light transmitting layer TPL may be disposed in the third pixel SP3.

The first wavelength conversion pattern WCL1 may include a first base resin BRS1 and first wavelength conversion materials WCP1 disposed in the first base resin BRS1. The second wavelength conversion pattern WCL2 may include a second base resin BRS2 and second wavelength conversion materials WCP2 disposed in the second base resin BRS2. The light transmitting layer TPL may include a third base resin BRS3 and scatterers SCP disposed in the third base resin BRS3.

The first through third base resins BRS1 through BRS3 may include a light-transmitting organic material. For example, the first through third base resins BRS1 through BRS3 may include epoxy resin, acrylic resin, cardo resin, or imide resin. The first through third base resins BRS1 through BRS3 may all be made of the same material, but the present disclosure is not limited thereto.

The scatterers SCP may be metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO) or tin oxide (SnO₂), and the organic particle material may be, for example, acrylic resin or urethane resin.

The first wavelength conversion materials WCP1 may convert the third color into the first color, and the second wavelength conversion materials WCP2 may convert the third color into the second color. The first wavelength conversion materials WCP1 and the second wavelength conversion materials WCP2 may be quantum dots, quantum rods, or phosphors. The quantum dots may include group IV nanocrystals, group II-VI compound nanocrystals. group III-V compound nanocrystals, group IV-VI nanocrystals, or a combination thereof. The first wavelength conversion pattern WCL1 and the second wavelength conversion pattern WCL2 may further include scatterers SCP to increase wavelength conversion efficiency.

The light transmitting layer TPL disposed in the third pixel SP3 may transmit light of the third color emitted from the light emitting layer LEL while maintaining the wavelength of the light. The scatterers SCP of the light transmitting layer TPL may control an emission path of light emitted through the light transmitting layer TPL. The light transmitting layer TPL may not include a wavelength conversion material.

The second capping layer 230 may be disposed on the wavelength conversion layer WCL, the light transmitting layer TPL, and the partition wall PTL. The second capping layer 230 may be made of an inorganic material. The second capping layer 230 may include a material selected from the materials listed as materials of the first capping layer 220. The second capping layer 230 and the first capping layer 220 may be made of the same material, but the present disclosure is not limited thereto.

The filler 300 may be disposed between the display substrate 100 and the color conversion substrate 200. The filler 300 may fill a space between the display substrate 100 and the color conversion substrate 200 and may bond and couple them to each other. The filler 300 may be disposed between the encapsulation structure 170 of the display substrate 100 and the second capping layer 230 of the color conversion substrate 200. The filler 300 may be made of, but not limited to, a Si-based organic material or an epoxy-based organic material.

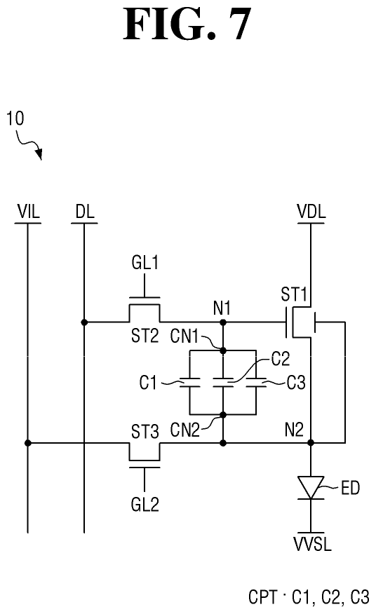

FIG. 7 is a circuit diagram of a pixel of the display device 10 according to the embodiment.

Referring to FIG. 7, each pixel SP may be connected to a first voltage line VDL, a data line DL, an initialization voltage line VIL, a first gate line GL1, a second gate line GL2, and a vertical voltage line VVSL.

Each pixel SP may include a pixel circuit and a light emitting element ED. The pixel circuit of each pixel SP may include first through third transistors ST1 through ST3 and a capacitor CPT.

The first transistor ST1 may include an upper gate electrode, a lower gate electrode, a drain electrode, and a source electrode. The first transistor ST1 may have the upper gate electrode connected to a first node N1, the lower gate electrode connected to a second node N2, the drain electrode connected to the first voltage line VDL, and the source electrode connected to the second node N2. The first transistor ST1 may control a drain-source current (or a driving current) based on a data voltage applied to the upper gate electrode and the lower gate electrode. The first transistor ST1 may be a driving transistor that drives the light emitting element ED.

The light emitting clement ED may emit light in response to a driving current received. The amount of light emitted from the light emitting element ED or the luminance of the light emitting clement ED may be proportional to the magnitude of the driving current. The light emitting element ED may be an organic light emitting diode including an organic light emitting layer, a quantum dot light emitting diode including a quantum dot light emitting layer, a micro light emitting diode, or an inorganic light emitting diode including an inorganic semiconductor.

A first electrode of the light emitting element ED may be connected to the second node N2, and a second electrode of the light emitting element ED may be connected to the vertical voltage line VVSL. The first electrode of the light emitting clement ED may be connected to the source electrode of the first transistor ST1, a drain electrode of the third transistor ST3, and a second capacitor electrode CN2 of the capacitor CPT through the second node N2.

The second transistor ST2 may be turned on by a first gate signal of the first gate line GL1 to electrically connect the data line DL and the first node N1 which is the upper gate electrode of the first transistor ST1. The second transistor ST2 may be turned on based on the first gate signal to supply a data voltage to the first node N1. The second transistor ST2 may have a gate electrode connected to the first gate line GL1, a drain electrode connected to the data line DL, and a source electrode connected to the first node N1. The source electrode of the second transistor ST2 may be connected to the upper gate electrode of the first transistor ST1 and a first capacitor electrode CN1 of the capacitor CPT through the first node N1. The second transistor ST2 may be a switching transistor that controls a current flowing through the first transistor ST1 and the light emitting element ED.

The third transistor ST3 may be turned on by a second gate signal of the second gate line GL2 to electrically connect the initialization voltage line VIL and the second node N2 which is the source electrode of the first transistor ST1. The third transistor ST3 may be turned on based on the second gate signal to supply an initialization voltage to the second node N2. The third transistor ST3 may be turned on based on the second gate signal to supply a sensing signal to the initialization voltage line VIL. The third transistor ST3 may have a gate electrode connected to the second gate line GL2, the drain electrode connected to the second node N2, and a source electrode connected to the initialization voltage line VIL. The drain electrode of the third transistor ST3 may be connected to the source electrode of the first transistor ST1 and the first electrode of the light emitting element ED through the second node N2 and may be connected to the second capacitor node CN2 of the capacitor CPT. The third transistor ST3 may be a switching transistor that controls a current flowing through the first transistor ST1 and the light emitting element ED.

The capacitor CPT may include a first capacitor C1, a second capacitor C2, and a third capacitor C3. The first capacitor C1, the second capacitor C2, and the third capacitor C3 may be connected in parallel to each other through the first capacitor node CN1 and the second capacitor node CN2. Accordingly, the total capacitance of the capacitor CPT may be equal to the sum of the respective capacitances of the first capacitor C1, the second capacitor C2, and the third capacitor C3.

One electrode of each of the first capacitor C1, the second capacitor C2, and the third capacitor C3 may be connected to the first node N1 through the first capacitor node CN1. The other electrode of each of the first capacitor C1, the second capacitor C2, and the third capacitor C3 may be connected to the second node N2 through the second capacitor node CN2.

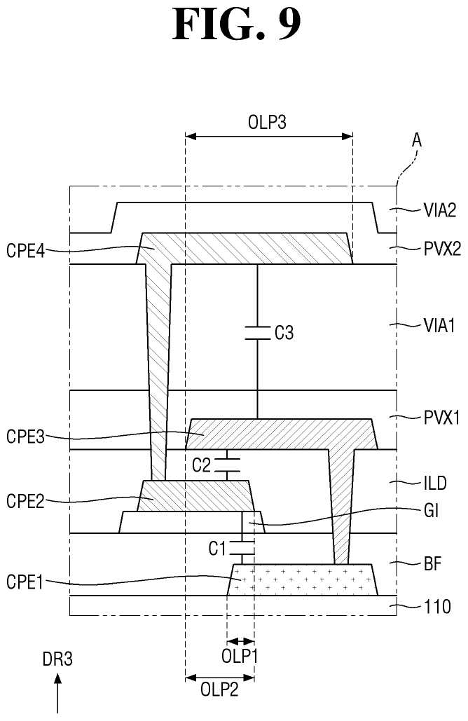

FIG. 8 is a cross-sectional view of the first transistor ST1 and the capacitor CPT of the display device 10 according to the embodiment. FIG. 9 is an enlarged view of area A of FIG. 8.

Referring to FIGS. 8 and 9 in addition to FIG. 7, the circuit layer CCL may be disposed on the first substrate 110. The circuit layer CCL (e.g., thin-film transistor layer) may include a first metal layer MTL1, a buffer layer BF, an active layer ACTL, a gate insulating layer GI, a second metal layer MTL2, an interlayer insulating layer ILD, a third metal layer MTL3, a first passivation layer PVX1, a first via layer VIA1, a fourth metal layer MTL4, a second passivation layer PVX2, and a second via layer VIA2.

The first metal layer MTL1 may be disposed on the first substrate 110. The first metal layer MTL1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. In an embodiment, the first metal layer MTL1 may include a lower gate electrode BGE of the first transistor ST1 and a first capacitor electrode CPE1 of the capacitor CPT.

The buffer layer BF may be disposed on the first metal layer MTL1. The buffer layer BF may be made of an inorganic material such as a silicon nitride layer, a silicon oxynitride layer, a silicon oxide layer, a titanium oxide layer, or an aluminum oxide layer. Alternatively, the buffer layer BF may be a multilayer in which a plurality of layers selected from a silicon nitride layer, a silicon oxynitride layer, a silicon oxide layer, a titanium oxide layer, and an aluminum oxide layer are alternately stacked.

The active layer ACTL may be disposed on the buffer layer BF. The active layer ACTL may be made of polycrystalline silicon, monocrystalline silicon, low-temperature polycrystalline silicon, amorphous silicon, or an oxide semiconductor material. In an embodiment, the active layer ACTL may include an active region ACT, a drain electrode DE, and a source electrode SE of the first transistor ST1.

The gate insulating layer GI may be disposed on the active layer ACTL. The gate insulating layer GI may be made of an inorganic layer such as a silicon nitride layer, a silicon oxynitride layer, a silicon oxide layer, a titanium oxide layer, or an aluminum oxide layer.

The second metal layer MTL2 may be disposed on the gate insulating layer GI. The second metal layer MTL2 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. In an embodiment, the second metal layer MTL2 may include an upper gate electrode UGE of the first transistor ST1 and a second capacitor electrode CPE2 of the capacitor CPT.

The interlayer insulating layer ILD may be disposed on the second metal layer MTL2. The interlayer insulating layer ILD may be made of an inorganic layer such as a silicon nitride layer, a silicon oxynitride layer, a silicon oxide layer, a titanium oxide layer, or an aluminum oxide layer. The interlayer insulating layer ILD may include a plurality of inorganic layers.

The third metal layer MTL3 may be disposed on the interlayer insulating layer ILD. The third metal layer MTL3 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. In an embodiment, the third metal layer MTL3 may include a first connection electrode CE1, a third connection electrode CE3, and a third capacitor electrode CPE3 of the capacitor CPT.

The first passivation layer PVX1 may be disposed on the third metal layer MTL3. The first passivation layer PVX1 may be made of an inorganic layer such as a silicon nitride layer, a silicon oxynitride layer, a silicon oxide layer, a titanium oxide layer, or an aluminum oxide layer.

The first via layer VIA1 may be disposed on the first passivation layer PVX1. The first via layer VIA1 may be made of an organic layer such as acryl resin, epoxy resin, phenolic resin, polyamide resin, or polyimide resin.

The fourth metal layer MTL4 may be disposed on the first via layer VIA1. The fourth metal layer MTL4 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. In an embodiment, the fourth metal layer MTL4 may include a second connection electrode CE2 and a fourth capacitor electrode CPE4 of the capacitor CPT.

The second passivation layer PVX2 may be disposed on the fourth metal layer MTL4. The second passivation layer PVX2 may be made of an inorganic layer such as a silicon nitride layer, a silicon oxynitride layer, a silicon oxide layer, a titanium oxide layer, or an aluminum oxide layer.

The second via layer VIA2 may be disposed on the second passivation layer PVX2. The second via layer VIA2 may be made of an organic layer such as acryl resin, epoxy resin, phenolic resin, polyamide resin, or polyimide resin.

The circuit layer CCL may include the first through third transistors ST1 through ST3 and the capacitor CPT. Since cross-sectional structures of the second and third transistors ST2 and ST3 are similar to the cross-sectional structure of the first transistor ST1, the first transistor ST1 will be described as an example for ease of description.

The first transistor ST1 may include the active region ACT, the upper gate electrode UGE, the lower gate electrode BGE, the drain electrode DE, and the source electrode SE.

The active region ACT may be disposed in the active layer ACTL. The active region ACT may overlap the upper gate electrode UGE. The active region ACT may be a non-conductive portion of the active layer ACTL in an area overlapping the upper gate electrode UGE.

The upper gate electrode UGE may be disposed in the second metal layer MTL2. As illustrated in FIG. 7, the upper gate electrode UGE may be connected to the first capacitor node CN1 of the capacitor CPT through the first node N1.

The lower gate electrode BGE may be disposed in the first metal layer MTL1. As illustrated in FIG. 7, the lower gate electrode BGE may be connected to the second capacitor node CN2 of the capacitor CPT through the second node N2.

In the drawings, the display device 10 is illustrated as including a double gate structure in which the upper gate electrode UGE and the lower gate electrode BGE are respectively disposed above and below the active region ACT. However, the present disclosure is not limited thereto. For example, the display device 10 may also include a top gate structure or a bottom gate structure by omitting any one of the upper gate electrode UGE and the lower gate electrode BGE.

The drain electrode DE and the source electrode SE may be formed by making the active layer ACTL conductive through heat treatment. The drain electrode DE and the source electrode SE may be made into N-type semiconductors, but the present disclosure is not limited thereto.

The drain electrode DE may be electrically connected to the first voltage line VDL as illustrated in FIG. 7. For example, as illustrated in FIG. 8, the drain electrode DE may be connected to the third connection electrode CE3. Although not illustrated in the drawing, the third connection electrode CE3 may be connected to the first voltage line VDL. Accordingly, the drain electrode DE may receive a driving voltage from the first voltage line VDL.

The source electrode SE may be connected to the light emitting element ED through the second node N2 as illustrated in FIG. 7. For example, as illustrated in FIG. 8, the source electrode SE may be connected to a pixel electrode PXE through the first connection electrode CE1 and the second connection electrode CE2. Accordingly, the source electrode SE may supply a driving current to the light emitting element ED.

The capacitor CPT may include the first capacitor electrode CPE1, the second capacitor electrode CPE2, the third capacitor electrode CPE3, and the fourth capacitor electrode CPE4.

The first capacitor electrode CPE1 may be disposed in the first metal layer MTL1. The second capacitor electrode CPE2 may be disposed in the second metal layer MTL2. The third capacitor electrode CPE3 may be disposed in the third metal layer MTL3. The fourth capacitor electrode CPE4 may be disposed in the fourth metal layer MTL4.

The first capacitor C1 may include the first capacitor electrode CPE1 and the second capacitor electrode CPE2. For example, one electrode of the first capacitor C1 may be the first capacitor electrode CPE1, and the other electrode may be the second capacitor electrode CPE2. The first capacitor C1 may be formed in a first overlap area OLP1 where the first capacitor electrode CPE1 and the second capacitor electrode CPE2 overlap.

The second capacitor C2 may include the second capacitor electrode CPE2 and the third capacitor electrode CPE3. For example, one electrode of the second capacitor C2 may be the second capacitor electrode CPE2, and the other electrode may be the third capacitor electrode CPE3. The second capacitor C2 may be formed in a second overlap area OLP2 where the second capacitor electrode CPE2 and the third capacitor electrode CPE3 overlap.

The third capacitor C3 may include the third capacitor electrode CPE3 and the fourth capacitor electrode CPE4. For example, one electrode of the third capacitor C3 may be the third capacitor electrode CPE3, and the other electrode may be the fourth capacitor electrode CPE4. The third capacitor C3 may be formed in a third overlap area OLP3 where the third capacitor electrode CPE3 and the fourth capacitor electrode CPE4 overlap.

In some embodiments, the second capacitor electrode CPE2 and the fourth capacitor electrode CPE4 may be connected to the first capacitor node CN1, and the first capacitor electrode CPE1 and the third capacitor electrode CPE3 may be connected to the second capacitor node CN2. Therefore, the second capacitor electrode CPE2 and the fourth capacitor electrode CPE4 may have the same potential as the upper gate electrode UGE of the first transistor ST1, and the first capacitor electrode CPE1 and the third capacitor electrode CPE3 may have the same potential as the source electrode SE and the lower gate electrode BGE of the first transistor ST1.

In the display device 10 according to the current embodiment, the area of the first overlap area OLP1 may be smaller than that of the second overlap area OLP2. In addition, the area of the second overlap area OLP2 may be smaller than that of the third overlap area OLP3. In the display device 10 according to the current embodiment, the area of each of the first through third capacitor electrodes CPE1 through CPE3 of the capacitor CPT may be minimized, but the total capacitance of the capacitor CPT may be increased.

More specifically, the first capacitor electrode CPE1 may be disposed in the same first metal layer MTL1 as the lower gate electrode BGE of the first transistor ST1. Therefore, since the first capacitor electrode CPE1 must be disposed in consideration of the lower gate electrode BGE, it may not be easy to increase the area of the first capacitor electrode CPE1. That is, it may not be easy to increase the area of the first overlap area OLP1.

In addition, the second capacitor electrode CPE2 may be disposed in the same second metal layer MTL2 as the upper gate electrode UGE of the first transistor ST1. Therefore, since the second capacitor electrode CPE2 must be disposed in consideration of the upper gate electrode UGE, it may not be easy to increase the area of the second capacitor electrode CPE2. That is, it may not be easy to increase the area of the second overlap area OLP2.

In the display device 10 according to the current embodiment, the third capacitor electrode CPE3 connected to the first capacitor electrode CPE1 may be disposed in the third metal layer MTL3, and the fourth capacitor electrode CPE4 connected to the second capacitor electrode CPE2 may be disposed in the fourth metal layer MTL4. Accordingly, the capacitance of the capacitor CPT may be increased.

For example, the area of the third overlap area OLP3 may be increased by increasing the area of the third capacitor electrode CPE3 disposed in the third metal layer MTL3 and the area of the fourth capacitor electrode CPE4 disposed in the fourth metal layer MTL4. Accordingly, the capacitance of the third capacitor C3 may increase, thereby increasing the total capacitance of the capacitor CPT.

In addition, since the third capacitor electrode CPE3 is disposed in the third metal layer MTL3 and the fourth capacitor electrode CPE4 is disposed in the fourth metal layer MTL4, line resistance between wirings of the first transistor ST1 and the capacitor CPT can be reduced.

The display device 10 may include a fifth metal layer MTL5 disposed on the circuit layer CCL.

The fifth metal layer MTL5 may be disposed on the circuit layer CCL. For example, the fifth metal layer MTL5 may be disposed on the second via layer VIA2. In an embodiment, the fifth metal layer MTL5 may include the pixel electrode PXE.

In the display device 10 according to the current embodiment, the pixel electrode PXE may include a different material from the first through fourth capacitor electrodes CPE1 through CPE4. For example, electrical conductivity of the first through fourth capacitor electrodes CPE1 through CPE4 may be higher than that of the pixel electrode PXE. Accordingly, the capacitance of the capacitor CPT may increase.

For example, as described above, the pixel electrode PXE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is located close to the light emitting layer LEL. The pixel electrode PXE may have, but is not limited to, a multilayer structure of ITO/Mg, ITO/MgF, ITO/Ag, or ITO/Ag/ITO.

Each of the first through fourth capacitor electrodes CPE1 through CPE4 respectively disposed in the first through fourth metal layers MTL1 through MTL4 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. In some embodiments, the first through fourth capacitor electrodes CPE1 through CPE4 may include the same material.

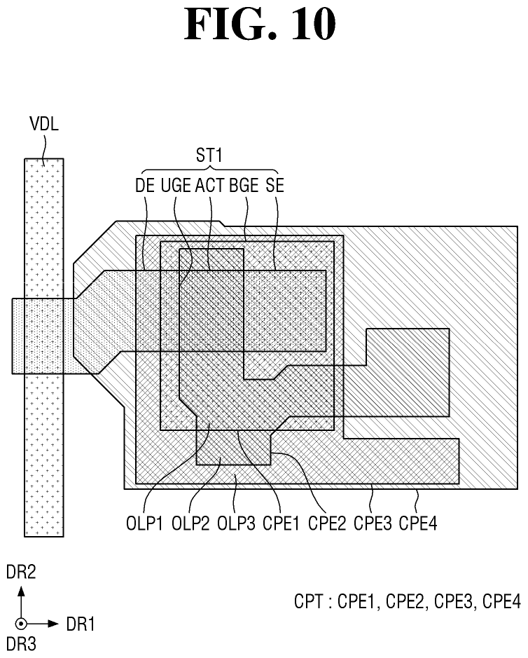

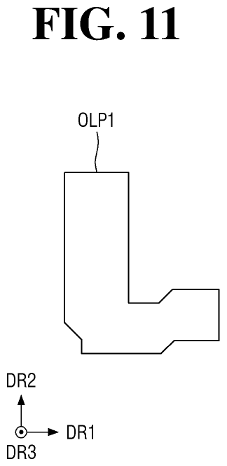

FIG. 10 is a schematic layout view of a part of the display device 10 according to the embodiment. FIGS. 11 through 13 are plan views of the first overlap area OLP1, the second overlap area OLP2, and the third overlap area OLP3 according to an embodiment. In FIG. 10, the first voltage line VDL, the first transistor ST1, and the capacitor CPT are illustrated while other elements are omitted.

Referring to FIGS. 10 through 13 in addition to FIGS. 8 and 9, the first voltage line VDL, the lower gate electrode BGE of the first transistor ST1, and the first capacitor electrode CPE1 of the capacitor CPT may be disposed in the first metal layer MTL1. The drain electrode DE, the active region ACT, and the source electrode SE of the first transistor ST1 may be disposed in the active layer ACTL. The upper gate electrode UGE of the first transistor ST1 and the second capacitor electrode CPE2 of the capacitor CPT may be disposed in the second metal layer MTL2. The third capacitor electrode CPE3 of the capacitor CPT may be disposed in the third metal layer MTL3. The fourth capacitor electrode CPE4 of the capacitor CPT may be disposed in the fourth metal layer MTL4.

In some embodiments, the first capacitor electrode CPE1 of the capacitor CPT may be a part of the lower gate electrode BGE of the first transistor ST1. For example, the first capacitor electrode CPE1 of the capacitor CPT may be integrally formed with the lower gate electrode BGE of the first transistor ST1. The first capacitor electrode CPE1 of the capacitor CPT and the lower gate electrode BGE of the first transistor ST1 may be physically connected to form one planar electrode.

In some embodiments, the second capacitor electrode CPE2 of the capacitor CPT may be a part of the upper gate electrode UGE of the first transistor ST1. For example, the second capacitor electrode CPE2 of the capacitor CPT may be integrally formed with the upper gate electrode UGE of the first transistor ST1. The second capacitor electrode CPE2 of the capacitor CPT and the upper gate electrode UGE of the first transistor ST1 may be physically connected to form one planar electrode.

As illustrated in FIGS. 11 through 13, the first overlap area OLP1 may be an area where the first capacitor electrode CPE1 and the second capacitor electrode CPE2 overlap. The second overlap area OLP2 may be an area where the second capacitor electrode CPE2 and the third capacitor electrode CPE3 overlap. The third overlap area OLP3 may be an area where the third capacitor electrode CPE3 and the fourth capacitor electrode CPE4 overlap.

In the display device 10 according to the current embodiment, the third overlap area OLP3 may be larger than the second overlap area OLP2, and the second overlap area OLP2 may be larger than the first overlap area OLP1. Accordingly, the area of each of the first through third capacitor electrodes CPE1 through CPE3 of the capacitor CPT may be minimized, but the total capacitance of the capacitor CPT may be increased.

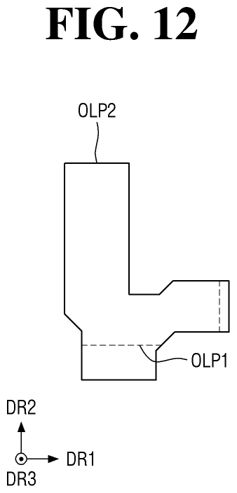

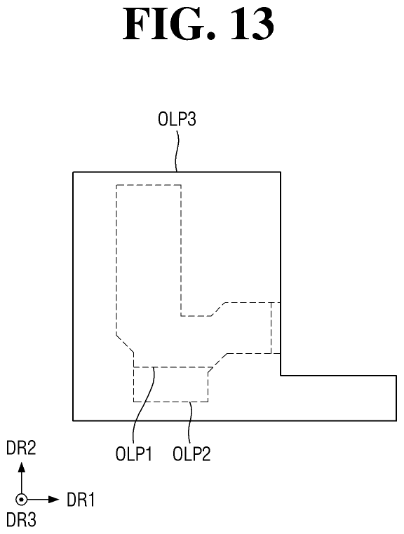

In some embodiments, as illustrated in FIGS. 12 and 13, the whole of the first overlap area OLP1 may overlap the second overlap area OLP2, and the whole of the second overlap area OLP2 may overlap the third overlap area OLP3. Accordingly, the display device 10 according to the current embodiment can increase the capacitance of the capacitor CPT even in a small area.

Hereinafter, other embodiments of the display device 10 according to the embodiment will be described. In the following embodiments, the same elements as those of the above-described embodiment are identified by the same reference characters, and any redundant description thereof will be omitted or given briefly, and differences will mainly be described.

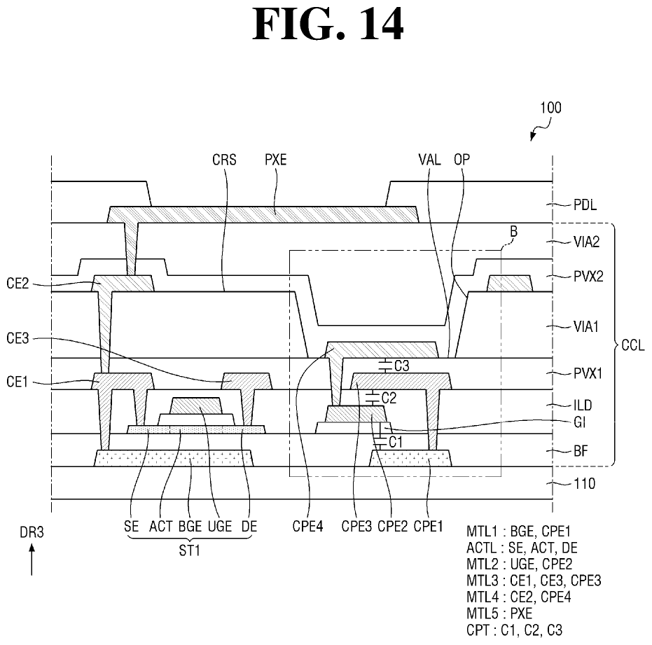

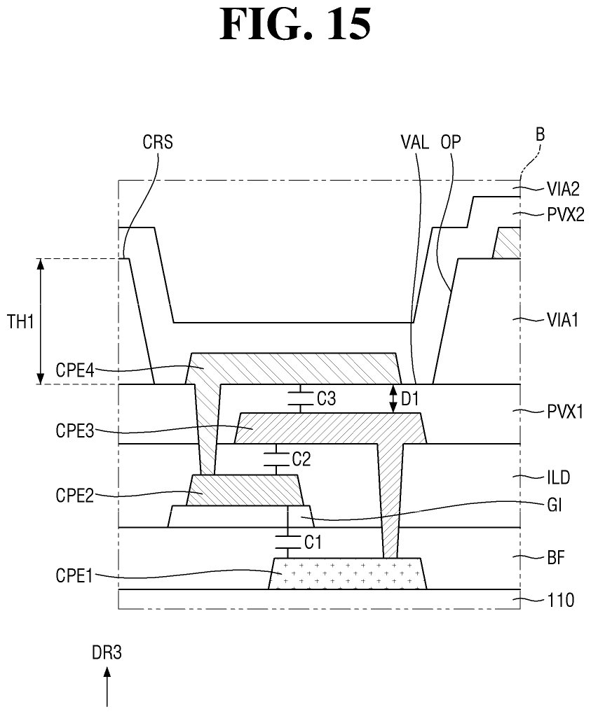

FIG. 14 is a cross-sectional view of a first transistor and a capacitor of a display device 10 according to an embodiment. FIG. 15 is an enlarged view of area B of FIG. 14.

Referring to FIGS. 14 and 15, the display device 10 according to the current embodiment is different from the display device 10 according to the embodiment described with reference to FIG. 8, etc. in that a first via layer VIA1 includes an opening OP to form a crest CRS and a valley VAL.

More specifically, the first via layer VIA1 may include the opening OP. The opening OP may overlap the capacitor CPT in the third direction DR3. A first passivation layer PVX1 may be exposed through the opening OP of the first via layer VIA1.

The first via layer VIA1 may include the valley VAL which is a lowest portion disposed within the opening OP and the crest CRS which is a highest portion disposed outside the opening OP. The valley VAL of the first via layer VIA1 may expose an upper surface of the first passivation layer PVX1.

A fourth capacitor electrode CPE4 may be disposed on the first passivation layer PVX1 exposed through the opening OP of the first via layer VIA1. The fourth capacitor electrode CPE4 may be disposed in the valley VAL of the first via layer VIA1. A second connection electrode CE2 may be disposed on the crest CRS of the first via layer VIA1. Accordingly, the fourth capacitor electrode CPE4 may be located at a lower level than the second connection electrode CE2.

In an embodiment, a thickness TH1 of the first via layer VIA1 may be about 1 to 3 μm. A height difference between the second connection electrode CE2 and the fourth capacitor electrode CPE4 in the third direction DR3 may be about 1 to 3 μm.

In the display device 10 according to the current embodiment, since the first via layer VIA1 includes the opening OP, the crest CRS and the valley VAL may be formed. Accordingly, a distance D1 between a third capacitor electrode CPE3 and the fourth capacitor electrode CPE4 in the third direction DR3 may be minimized. Therefore, the capacitance of a third capacitor C3 may increase, thereby increasing the total capacitance of the capacitor CPT.

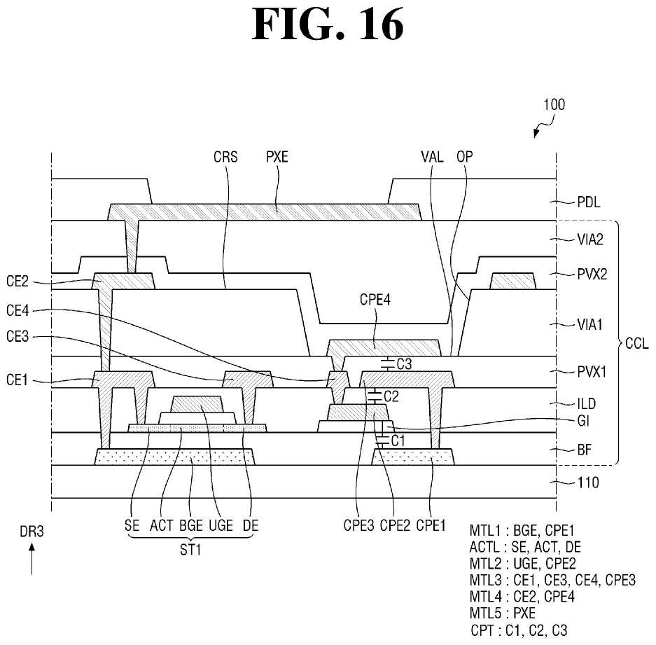

FIG. 16 is a cross-sectional view of a first transistor and a capacitor of a display device 10 according to an embodiment.

Referring to FIG. 16, the display device 10 according to the current embodiment is different from the display device 10 according to the embodiment described with reference to FIG. 14, etc. in that it further includes a fourth connection electrode CE4.

More specifically, the display device 10 according to the current embodiment may further include the fourth connection electrode CE4 disposed in a third metal layer MTL3. The fourth connection electrode CE4 may be disposed between a second capacitor electrode CPE2 and a fourth capacitor electrode CPE4. The fourth connection electrode CE4 may electrically connect the second capacitor electrode CPE2 and the fourth capacitor electrode CPE4.

Since the fourth connection electrode CE4 is disposed between the second capacitor electrode CPE2 and the fourth capacitor electrode CPE4 in the display device 10 according to the current embodiment, the reliability of the display device 10 can be improved.

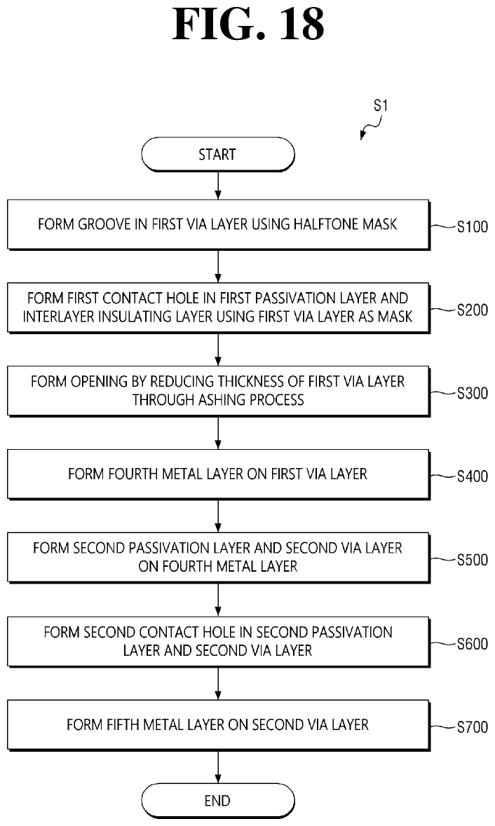

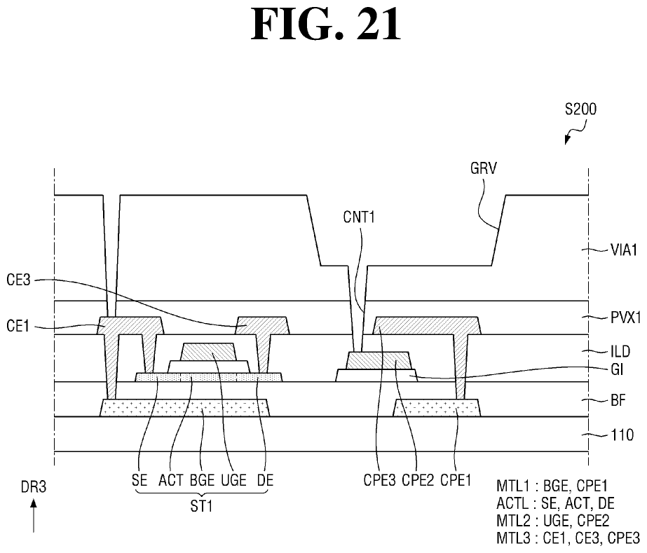

For example, as in the display device 10 according to the embodiment described with reference to FIG. 14, etc., a first contact hole CNT1 (see FIG. 21) may be formed to pass through both a first passivation layer PVX1 and an interlayer insulating layer ILD so that the fourth capacitor electrode CPE4 is connected to the second capacitor electrode CPE2. As in operation S200 (see FIG. 21) of a method S1 (see FIG. 18) of manufacturing a display device which will be described later, when the first contact hole CNT1 (see FIG. 21) is formed, a contact hole in which a second connection electrode CE2 of the first transistor ST1 is to be positioned may also be formed. Here, while the first contact hole CNT1 is formed by simultaneously etching the first passivation layer PVX1 and the interlayer insulating layer ILD, the contact hole in which the second connection electrode CE2 is to be positioned may be formed by etching only the first passivation layer PVX1. Since the display device 10 according to the current embodiment further includes the fourth connection electrode CE4, this difference in the required degree of etching can be removed. Therefore, the reliability of the display device 10 can be improved.

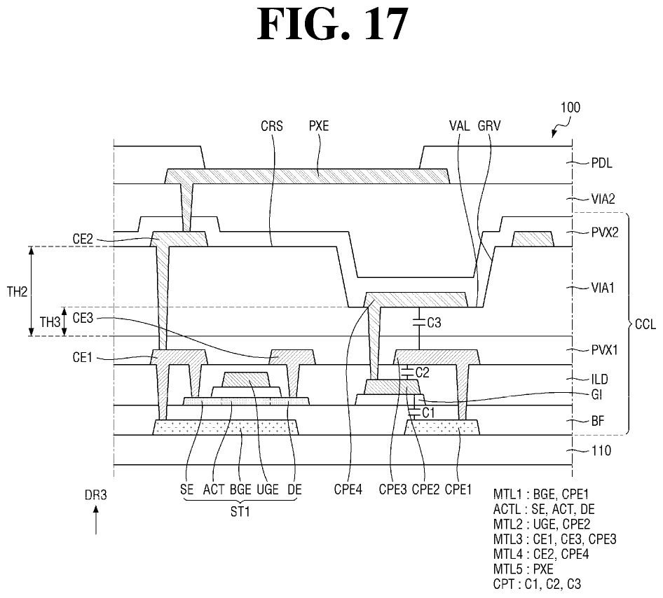

FIG. 17 is a cross-sectional view of a first transistor and a capacitor of a display device 10 according to an embodiment.

Referring to FIG. 17, the display device 10 according to the current embodiment is different form the display device 10 according to the embodiment described with reference to FIG. 14, etc. in that a first via layer VIA1 includes a groove GRV instead of an opening OP.

More specifically, the first via layer VIA1 may include the groove GRV. The groove GRV may overlap the capacitor CPT in the third direction DR3.

The first via layer VIA1 may include a valley VAL which is a lowest portion disposed within the groove GRV and a crest CRS which is a highest portion disposed outside the groove GRV.

A fourth capacitor electrode CPE4 may be disposed on the valley VAL of the first via layer VIA1 disposed in the groove GRV of the first via layer VIA1. The fourth capacitor electrode CPE4 may be disposed in the valley VAL of the first via layer VIA1. A second connection electrode CE2 may be disposed on the crest CRS of the first via layer VIA1. Accordingly, the fourth capacitor electrode CPE4 may be located at a lower level than the second connection electrode CE2.

In an embodiment, a thickness TH2 of the crest CRS of the first via layer VIA1 may be about 1.5 to 4.5 μm. A thickness TH3 of the valley VAL of the first via layer VIA1 may be about 0.5 to 1.5 μm.

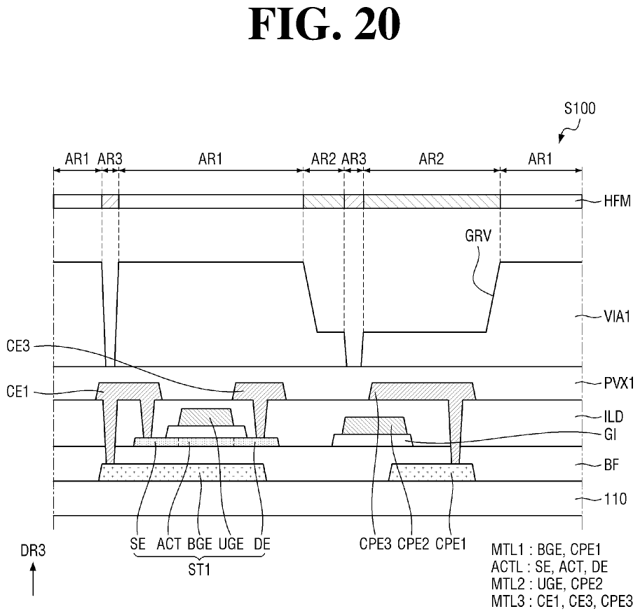

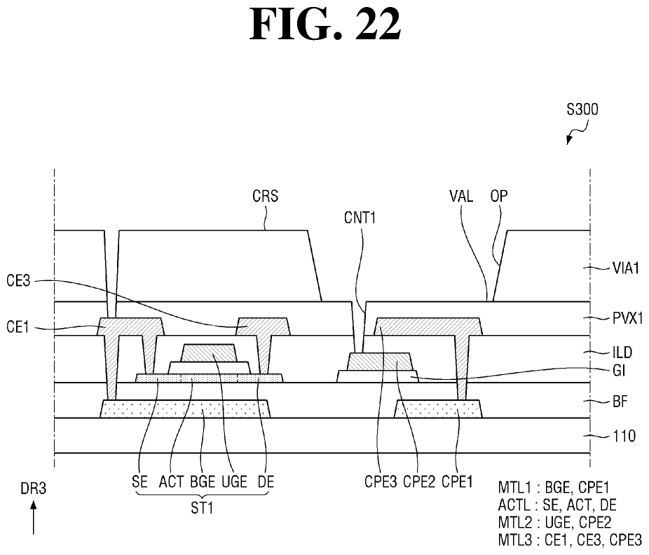

The display device 10 according to the current embodiment may be formed when a thickness of the first via layer VIA1 is not reduced by not performing an ashing process in operation S300 (see FIG. 22) of the method S1 (see FIG. 18) of manufacturing a display device which will be described later. For example, when a fourth metal layer MTL4 is stacked while the shape of the groove GRV formed in operation S100 (see FIG. 20) is maintained as it is, a display device shaped like the display device 10 according to the current embodiment may be formed. Accordingly, since the ashing process is not performed, process efficiency can be improved.

A method of manufacturing a display device according to an embodiment will now be described. For case of description, a method of manufacturing the display device according to the embodiment of FIG. 14 will be described as an example.

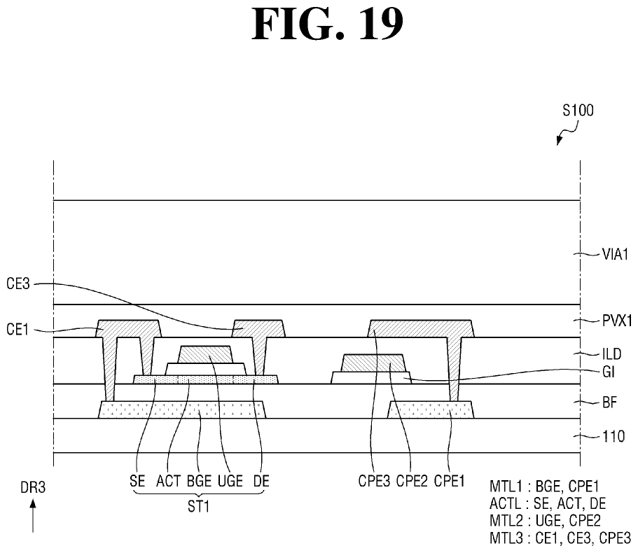

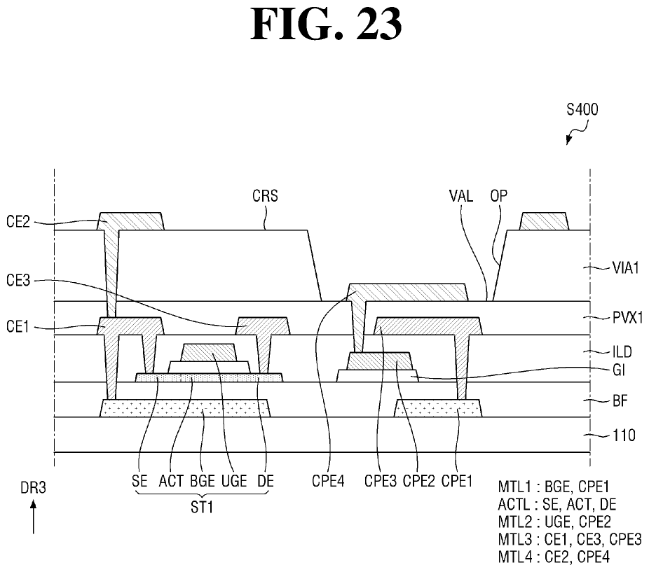

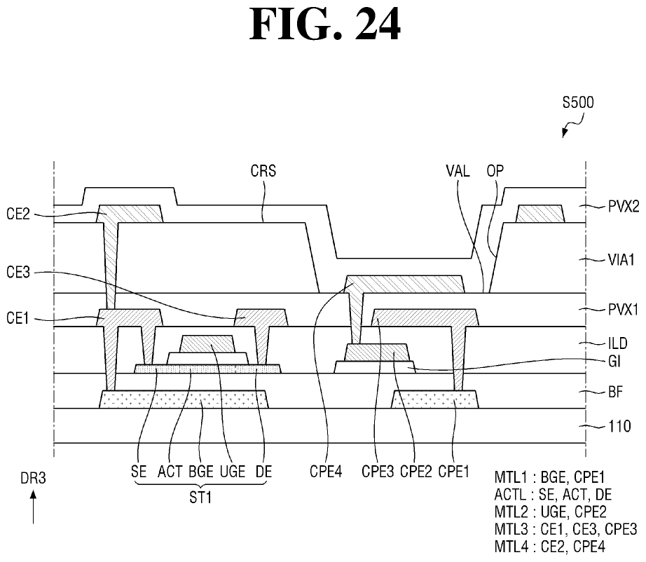

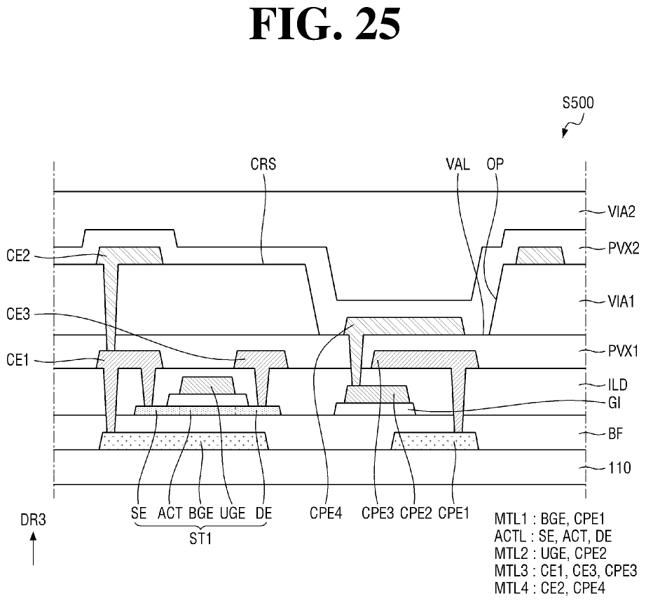

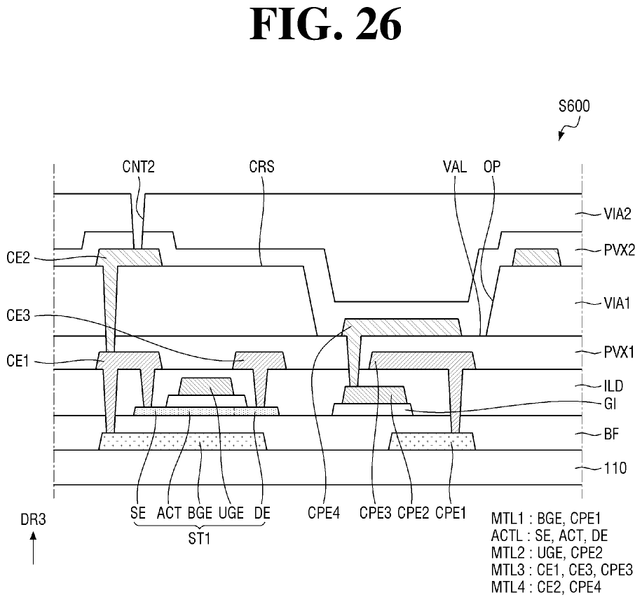

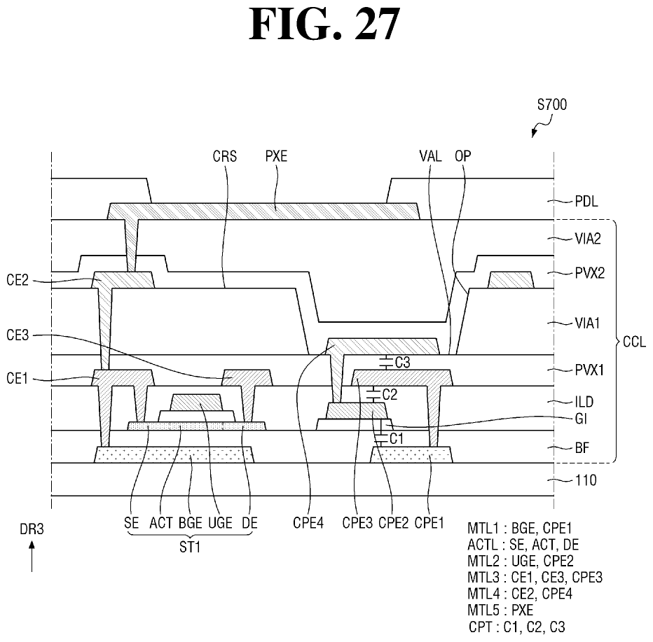

FIG. 18 is a flowchart illustrating a method of manufacturing the display device according to the embodiment of FIG. 14. FIGS. 19 and 20 are cross-sectional views illustrating operation S100 of FIG. 18. FIG. 21 is a cross-sectional view illustrating operation S200 of FIG. 18. FIG. 22 is a cross-sectional view illustrating operation S300 of FIG. 18. FIG. 23 is a cross-sectional view illustrating operation S400 of FIG. 18. FIGS. 24 and 25 are cross-sectional views illustrating operation S500 of FIG. 18. FIG. 26 is a cross-sectional view illustrating operation S600 of FIG. 18. FIG. 27 is a cross-sectional view illustrating operation S700 of FIG. 18.

Referring to FIGS. 18 through 27, the method SI of manufacturing the display device according to the embodiment may include forming a groove in a first via layer using a halftone mask (operation S100), forming a first contact hole in a first passivation layer and an interlayer insulating layer using the first via layer as a mask (operation S200), forming an opening by reducing a thickness of the first via layer through an ashing process (operation S300), forming a fourth metal layer on the first via layer (operation S400), forming a second passivation layer and a second via layer on the fourth metal layer (operation S500), forming a second contact hole in the second passivation layer and the second via layer (operation S600), and forming a fifth metal layer on the second via layer (operation S700).

First, as illustrated in FIGS. 19 and 20, in the forming of the groove in the first via layer using the halftone mask (operation S100), a first via layer VIA1 may be formed on a first passivation layer PVX1. The first via layer VIA1 may be made of an organic layer such as acryl resin, epoxy resin, phenolic resin, polyamide resin, or polyimide resin.

Next, a groove GRV may be formed in the first via layer VIA1 through a photolithography process. A halftone mask HFM may be used in the photolithography process. The halftone mask HFM may be a mask in which areas having different transmittances exist in a mask. For example, the halftone mask HFM may include a first area AR1, a second area AR2, and a third area AR3 having different transmittances.

When the halftone mask HFM uses a positive method, transmittance may be higher in the order of the third area AR3, the second area AR2, and the first area AR1. When the halftone mask HFM uses a negative method, transmittance may be higher in the order of the first area AR1, the second area AR2, and the third area AR3.

A thickness of the first via layer VIA1 may be greater in the order of the first area AR1, the second area AR2, and the third area AR3. A hole may be formed in the third area AR3 to expose the first passivation layer PVX1, and the groove GRV may be formed in the second area AR2 to form a valley.

Second, as illustrated in FIG. 21, in the forming of the first contact hole in the first passivation layer and the interlayer insulating layer using the first via layer as the mask (operation S200), the first passivation layer PVX1 and an interlayer insulating layer ILD may be etched to form a contact hole exposing a second metal layer MTL2 and a third metal layer MTL3. In an embodiment, the first passivation layer PVX1 and the interlayer insulating layer ILD may be etched through dry etching, but the present disclosure is not limited thereto.

For example, a portion of the first passivation layer PVX1 may be etched to form a contact hole that exposes a first connection electrode CE1 connected to a first transistor ST1. In addition, portions of the first passivation layer PVX1 and the interlayer insulating layer ILD may be etched to form a first contact hole CNT1 that exposes a second capacitor electrode CPE2 of a capacitor CPT.

In some embodiments, as described above with reference to FIG. 16, when a fourth connection electrode CE4 (see FIG. 16) is disposed in the third metal layer MTL3, the first contact hole CNT1 may pass through only the first passivation layer PVX1 and may not pass through the interlayer insulating layer ILD.

Third, as illustrated in FIG. 22, in the forming of the opening by reducing the thickness of the first via layer through the ashing process (operation S300), the thickness of the first via layer VIA1 may be reduced through an ashing process.

As the thickness of the first via layer VIA1 is reduced, the groove GRV located in the second area AR2 may be changed into an opening OP. A portion of the first passivation layer PVX1 may be exposed through the opening OP of the first via layer VIA1.

In some embodiments, as described above with reference to FIG. 17, operation S300 may be omitted from the method S1 of manufacturing the display device. In this case, as in the display device 10 according to the embodiment of FIG. 17, the first via layer VIA1 may include the groove GRV instead of the opening OP.

Fourth, as illustrated in FIG. 23, in the forming of the fourth metal layer on the first via layer (operation S400), a fourth metal layer MTL4 may be formed on the first via layer VIA1. The fourth metal layer MTL4 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The fourth metal layer MTL4 may include a second connection electrode CE2 connected to the first transistor ST1 and a fourth capacitor electrode CPE4 of the capacitor CPT. The second connection electrode CE2 may be disposed on a crest CRS of the first via layer VIA1, and the fourth capacitor electrode CPE4 may be disposed in a valley VAL located within the opening OP of the first via layer VIA1.

As in the display device 10 according to the embodiment of FIG. 14, when the first via layer VIA1 includes the opening OP, the fourth capacitor electrode CPE4 may be disposed on the first passivation layer PVX1. As in the display device 10 according to the embodiment of FIG. 17, when the first via layer VIA1 includes the groove GRV, the fourth capacitor electrode CPE4 may be disposed on the first via layer VIA1.

Fifth, as illustrated in FIGS. 24 and 25, in the forming of the second passivation layer and the second via layer on the fourth metal layer (operation S500), a second passivation layer PVX2 may be formed on the fourth metal layer MTL4. The second passivation layer PVX2 may be made of an inorganic layer such as a silicon nitride layer, a silicon oxynitride layer, a silicon oxide layer, a titanium oxide layer, or an aluminum oxide layer.

A second via layer VIA2 may be formed on the second passivation layer PVX2. The second via layer VIA2 may be made of an organic layer such as acryl resin, epoxy resin, phenolic resin, polyamide resin, or polyimide resin.

Sixth, as illustrated in FIG. 26, in the forming of the second contact hole in the second passivation layer and the second via layer (operation S600), the second passivation layer PVX2 and the second via layer VIA2 may be etched to form a contact hole that exposes the fourth metal layer MTL4. In an embodiment, the second passivation layer PVX2 and the second via layer VIA2 may be etched through dry etching, but the present disclosure is not limited thereto.

In an embodiment, as in operation S200, after the second via layer VIA2 is patterned through a photoresist process, the second passivation layer PVX2 may be etched using the patterned second via layer VIA2 as a mask.

Seventh, as illustrated in FIG. 27, in the forming of the fifth metal layer on the second via layer (operation S700), a fifth metal layer MTL5 may be formed on the second via layer VIA2. The fifth metal layer MTL5 may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof.

In concluding the detailed description, those skilled in the art will appreciate that many variations and modifications can be made to the preferred embodiments without substantially departing from the principles of the present disclosure. Therefore, the disclosed preferred embodiments of the invention are used in a generic and descriptive sense only and not for purposes of limitation.

What is claimed is:

1. A display device comprising:
a substrate;
a first metal layer disposed on the substrate;
an active layer disposed on the first metal layer;
a second metal layer disposed on the active layer;
a third metal layer disposed on the second metal layer;
a fourth metal layer disposed on the third metal layer; and
a transistor and a capacitor disposed on the substrate,
wherein the transistor comprises:
a gate electrode disposed in at least any one of the first metal layer and the second metal layer; and
a drain electrode, a source electrode and an active region disposed in the active layer, and
wherein the capacitor comprises:
a first capacitor comprising a first electrode disposed in the first metal layer and a second electrode disposed in the second metal layer;
a second capacitor comprising the second electrode and a third electrode disposed in the third metal layer; and
a third capacitor comprising the third electrode and a fourth electrode disposed in the fourth metal layer.

2. The display device of claim 1, further comprising:
a first connection electrode disposed in the fourth metal layer and electrically connected to at least any one of the drain electrode and the source electrode; and
a light emitting element disposed on the fourth metal layer and connected to the first connection electrode.

3. The display device of claim 2, comprising:
a first overlap area in which the first electrode and the second electrode overlap;
a second overlap area in which the second electrode and the third electrode overlap; and
a third overlap area in which the third electrode and the fourth electrode overlap,
wherein an area of the third overlap area is larger than an area of each of the first overlap area and an area of the second overlap area.

4. The display device of claim 3, wherein the whole of the first overlap area and the whole of the second overlap area overlap the third overlap area.

5. The display device of claim 2, wherein
the light emitting element comprises a pixel electrode connected to the first connection electrode, and
the pixel electrode comprises a different material from at least any one of the first through fourth electrodes.

6. The display device of claim 5, wherein electrical conductivity of at least any one of the first through fourth electrodes is higher than electrical conductivity of the pixel electrode.

7. The display device of claim 5, wherein
the pixel electrode comprises at least any one of indium-tin-oxide (ITO), indium-zinc-oxide (IZO), zinc oxide (ZnO) and indium oxide (In₂O₃) and at least any one of silver (Ag), magnesium (Mg), aluminum (Al), platinum (Pt), lead (Pb), gold (Au), nickel (Ni), neodymium (Nd), iridium (Ir), chromium (Cr), lithium (Li) and calcium (Ca), and
at least any one of the first through fourth electrodes comprises at least any one of molybdenum (Mo), aluminum (Al), chromium (Cr), gold (Au), titanium (Ti), nickel (Ni), neodymium (Nd) and copper (Cu).

8. The display device of claim 2, further comprising a first via layer disposed between the third metal layer and the fourth metal layer, wherein
the first via layer comprises an opening or a groove overlapping the capacitor, and
the fourth electrode is disposed in the opening or the groove.

9. The display device of claim 8, wherein the fourth electrode is located at a lower level than the first connection electrode.

10. The display device of claim 9, further comprising a second connection electrode disposed in the third metal layer and connecting at least any one of the drain electrode and the source electrode to the first connection electrode,
wherein a distance between the third electrode and the fourth electrode is smaller than a distance between the first connection electrode and the second connection electrode, in a thickness direction of the substrate.

11. The display device of claim 8, further comprising a first passivation layer disposed between the first via layer and the third metal layer, wherein
the via layer comprises the opening,
the first passivation layer is exposed through the opening, and
the fourth electrode is disposed on the first passivation layer exposed through the opening.

12. The display device of claim 8, wherein
the via layer comprises the groove,
the first via layer comprises a valley which is a lowest surface disposed within the groove and a crest which is a highest surface disposed outside the groove, and
the fourth electrode is disposed in the valley.

13. The display device of claim 8, further comprising a third connection electrode disposed in the third metal layer,
wherein the third connection electrode is disposed between the fourth electrode and the second electrode.

14. The display device of claim 13, wherein the third connection electrode electrically connects the fourth electrode and the second electrode to each other.

15. The display device of claim 1, wherein
the second electrode and the fourth electrode are electrically connected to each other, and
the first electrode and the third electrode are electrically connected to each other.

16. The display device of claim 1, wherein
the gate electrode disposed in the first metal layer is a lower gate electrode,
the gate electrode disposed in the second metal layer is an upper gate electrode,
the first electrode and the third electrode have the same potential as at least any one of the source electrode and the lower gate electrode, and
the second electrode and the fourth electrode have the same potential as the upper gate electrode.

17. The display device of claim 16, wherein the second electrode is a part of the upper gate electrode.

18. The display device of claim 17, wherein the first electrode is a part of the lower gate electrode.

19. A display device comprising:
a substrate;
a first metal layer disposed on the substrate;
a second metal layer disposed on the first metal layer;
a third metal layer disposed on the second metal layer;
a first via layer disposed on the third metal layer and comprising a valley and a crest;
a fourth metal layer disposed on the first via layer; and
a capacitor disposed on the substrate,
wherein the capacitor comprises:
a first electrode disposed in the first metal layer;
a second electrode disposed in the second metal layer;
a third electrode disposed in the third metal layer; and
a fourth electrode disposed in the fourth metal layer, and
wherein the fourth electrode is disposed in the valley of the first via layer.

20. The display device of claim 19, wherein
the second electrode and the fourth electrode are electrically connected to each other, and
the first electrode and the third electrode are electrically connected to each other.

21. A method of manufacturing a display device which comprises a substrate, a first metal layer disposed on the substrate, a second metal layer disposed on the first metal layer, a third metal layer disposed on the second metal layer, a first via layer disposed on the third metal layer, and a capacitor disposed on the substrate, the method comprising:
forming a groove in the first via layer using a halftone mask; and
forming a fourth metal layer on the first via layer,
wherein the capacitor comprises:
a first electrode disposed in the first metal layer;
a second electrode disposed in the second metal layer;
a third electrode disposed in the third metal layer; and
a fourth electrode disposed in the fourth metal layer, and the fourth electrode is formed in the groove.

22. The method of claim 21, further comprising forming an opening by reducing a thickness of the first via layer after the forming of the groove,
wherein the fourth electrode is formed in the opening in the forming of the fourth electrode.
